(19) United States
(12) Patent Application Publication
(10) Pub. No.: US 2023/0036693 A1
(43) Pub. Date: Feb. 2, 2023

(54) Semiconductor Devices and Methods of Manufacture

(71) Applicant: Taiwan Semiconductor Manufacturing Co., Ltd., Hsinchu (TW)

(72) Inventors: Kan-Ju Lin, Kaohsiung City (TW); Chien Chang, Hsinchu (TW); Chih-Shiun Chou, Hsinchu (TW); Tai Min Chang, Taipei City (TW); Yi-Ning Tai, Taoyuan (TW); Hung-Yi Huang, Hsinchu (TW); Chih-Wei Chang, Hsinchu (TW); Ming-Hsing Tsai, Chu-Pei City (TW); Lin-Yu Huang, Hsinchu (TW)

(21) Appl. No.: 17/675,558

(22) Filed: Feb. 18, 2022

Related U.S. Application Data
(60) Provisional application No. 63/226,836, filed on Jul. 29, 2021.

(51) Int. Cl. H01L 21/768; H01L 29/78; H01L 23/535; H01L 21/311; H01L 29/66

(52) U.S. Cl. CPC H01L 21/76826; H01L 29/7851; H01L 23/535; H01L 21/31116; H01L 21/31144; H01L 21/76805; H01L 21/76895; H01L 29/66795

(57) ABSTRACT

Semiconductor devices and methods of manufacturing are provided. In some embodiments the method includes depositing an etch stop layer over a first hard mask material, the first hard mask material over a gate stack, depositing an interlayer dielectric over the etch stop layer, forming a first opening through the interlayer dielectric, the etch stop layer, and the first hard mask material, the first opening exposing a conductive portion of the gate stack, and treating sidewalls of the first opening with a first dopant to form a first treated region within the interlayer dielectric, a second treated region within the etch stop layer, a third treated region within the first hard mask material, and a fourth treated region within the conductive portion, wherein after the treating the fourth treated region has a higher concentration of the first dopant than the first treated region.

### PRIORITY CLAIM

This application claims the benefit of U.S. Provisional Application No. 63/226,836, filed on Jul. 29, 2021, which application is hereby incorporated herein by reference.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate a finFET, in accordance with some embodiments.

FIG. 2 illustrates deposition of interlayer dielectric, in accordance with some embodiments.

FIG. 3 illustrates formation of an opening through the interlayer dielectric, in accordance with some embodiments.

FIG. 4 illustrates a treatment, in accordance with some embodiments.

FIG. 5 illustrates deposition of a conductive material, in accordance with some embodiments.

FIG. 6 illustrates a planarization process, in accordance with some embodiments.

FIG. 7 illustrates a dielectric recap, in accordance with some embodiments.

FIG. 8 illustrates formation of a second opening, in accordance with some embodiments.

FIG. 9 illustrates formation of a recess, in accordance with some embodiments.

FIG. 10 illustrates a second treatment, in accordance with some embodiments.

FIG. 11 illustrates deposition of a conductive material, in accordance with some embodiments.

FIG. 12A illustrates a planarization process, in accordance with some embodiments.

FIG. 12B illustrates formation of an interconnect, in accordance with some embodiments.

FIGS. 13A-13b illustrate a process without the second treatment, in accordance with some embodiments.

FIG. 14A-14C illustrate a process without the recess, in accordance with some embodiments.

FIGS. 15A-15B illustrate a process without the second treatment and without the recess, in accordance with some embodiments.

FIGS. 16A-16E illustrate a process with a second hard mask material, in accordance with some embodiments.

FIGS. 17A-17D illustrate a process with a second hard mask material and a recess, in accordance with some embodiments.

FIGS. 18A-18C illustrate a process with a single treatment, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments will now be described with respect to particular examples including finFET devices with a pseudo bottom-up plug process that works to enable scaling as devices are reduced in size. However, embodiments are not limited to the examples provided herein, and the ideas may be implemented in a wide array of embodiments, such as nanowire devices, nanosheet devices, or silicon on insulator structures.

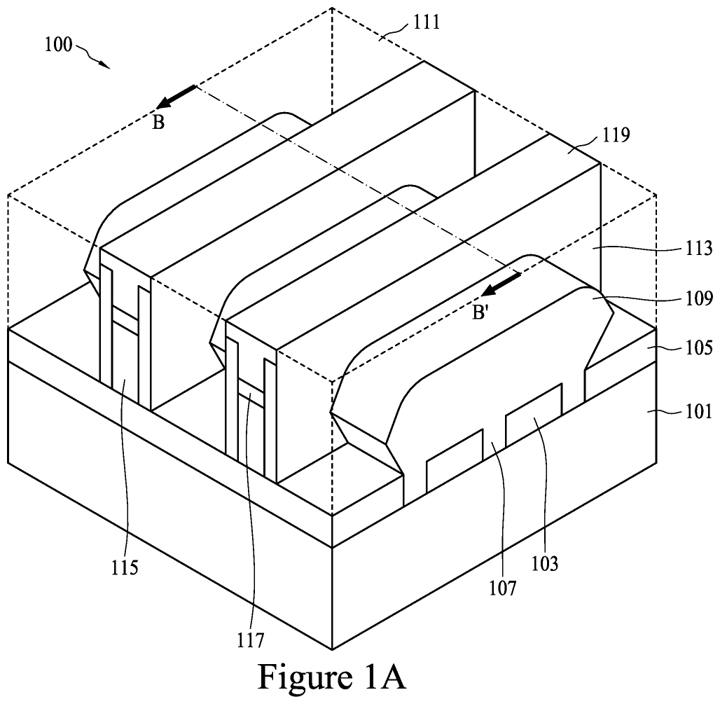

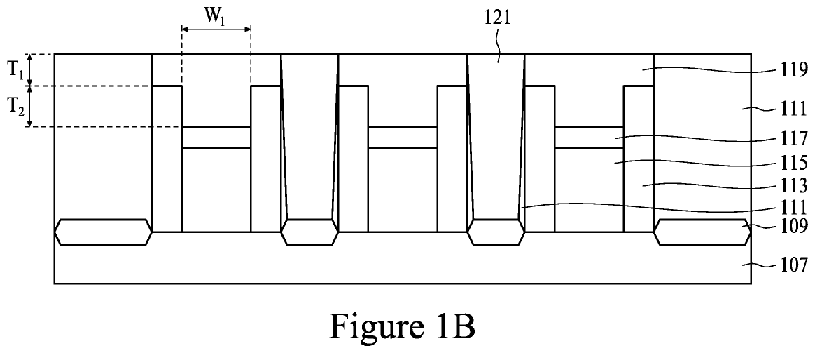

With reference now to FIG. 1A, there is illustrated a perspective view of a semiconductor device 100 such as a finFET device. In an embodiment the semiconductor device 100 comprises a substrate 101 and first trenches 103. The substrate 101 may be a silicon substrate, although other substrates, such as semiconductor-on-insulator (SOI), strained SOI, and silicon germanium on insulator, could be used. The substrate 101 may be a p-type semiconductor, although in other embodiments, it could be an n-type semiconductor.

In other embodiments the substrate 101 may be chosen to be a material which boosts the performance (e.g., boost the carrier mobility) of the devices formed from the substrate 101. For example, in some embodiments the material of the substrate 101 may be chosen to be a layer of epitaxially grown semiconductor material, such as epitaxially grown silicon germanium which helps to boost some of the measurements of performance of devices formed from the epitaxially grown silicon germanium. However, while the use of these materials may be able to boost some of the performance characteristics of the devices, the use of these same materials may affect other performance characteristics of the device. For example, the use of epitaxially grown silicon germanium may degrade (with respect to silicon) the interfacial defects of the device.

The first trenches 103 may be formed as an initial step in the eventual formation of first isolation regions 105. The first trenches 103 may be formed using a masking layer (not separately illustrated in FIG. 1A) along with a suitable etching process. For example, the masking layer may be a hard mask comprising silicon nitride formed through a process such as chemical vapor deposition (CVD), although other materials, such as oxides, oxynitrides, silicon carbide, combinations of these, or the like, and other processes, such as plasma enhanced chemical vapor deposition (PECVD), low pressure chemical vapor deposition (LPCVD), or even silicon oxide formation followed by nitridation, may be utilized. Once formed, the masking layer may be patterned through a suitable photolithographic process to expose those portions of the substrate 101 that may be removed to form the first trenches 103.

As one of skill in the art will recognize, however, the processes and materials described above to form the masking layer are not the only method that may be used to protect portions of the substrate 101 while exposing other portions of the substrate 101 for the formation of the first trenches 103. Any suitable process, such as a patterned and developed photoresist, may be utilized to expose portions of the substrate 101 to be removed to form the first trenches 103. All such methods may be fully intended to be included in the scope of the present embodiments.

Once a masking layer has been formed and patterned, the first trenches 103 are formed in the substrate 101. The exposed substrate 101 may be removed through a suitable process such as reactive ion etching (RIE) in order to form the first trenches 103 in the substrate 101, although any suitable process may be used. In an embodiment, the first trenches 103 may be formed to have a first depth of less than about 5,000 Å from the surface of the substrate 101, such as about 2,500 Å.

However, as one of ordinary skill in the art will recognize, the process described above to form the first trenches 103 is merely one potential process, and is not meant to be the only embodiment. Rather, any suitable process through which the first trenches 103 may be formed may be utilized and any suitable process, including any number of masking and removal steps may be used.

In addition to forming the first trenches 103, the masking and etching processes additionally form fins 107 from those portions of the substrate 101 that remain unremoved. For convenience the fins 107 have been illustrated in the figures as being separated from the substrate 101 by a dashed line, although a physical indication of the separation may or may not be present. These fins 107 may be used, as discussed below, to form the channel region of multiple-gate FinFET transistors. While FIG. 1A only illustrates three of the fins 107 formed from the substrate 101, any number of fins 107 may be utilized.

The fins 107 may be formed such that they have a width at the surface of the substrate 101 of between about 5 nm and about 80 nm, such as about 30 nm. Additionally, the fins 107 may be spaced apart from each other by a distance of between about 10 nm and about 100 nm, such as about 50 nm. By spacing the fins 107 in such a fashion, the fins 107 may each form a separate channel region while still being close enough to share a common gate (discussed further below).

Furthermore, the fins 107 may be patterned by any suitable method. For example, the fins 107 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 107.

Once the first trenches 103 and the fins 107 have been formed, the first trenches 103 may be filled with a dielectric material and the dielectric material may be recessed within the first trenches 103 to form the first isolation regions 105. The dielectric material may be an oxide material, a high-density plasma (HDP) oxide, or the like. The dielectric material may be formed, after an optional cleaning and lining of the first trenches 103, using either a chemical vapor deposition (CVD) method (e.g., the HARP process), a high density plasma CVD method, or other suitable method of formation as is known in the art.

The first trenches 103 may be filled by overfilling the first trenches 103 and the substrate 101 with the dielectric material and then removing the excess material outside of the first trenches 103 and the fins 107 through a suitable process such as chemical mechanical polishing (CMP), an etch, a combination of these, or the like. In an embodiment, the removal process removes any dielectric material that is located over the fins 107 as well, so that the removal of the dielectric material may expose the surface of the fins 107 to further processing steps.

Once the first trenches 103 have been filled with the dielectric material, the dielectric material may then be recessed away from the surface of the fins 107. The recessing may be performed to expose at least a portion of the sidewalls of the fins 107 adjacent to the top surface of the fins 107. The dielectric material may be recessed using a wet etch by dipping the top surface of the fins 107 into an etchant such as HF, although other etchants, such as H₂, and other methods, such as a reactive ion etch, a dry etch with etchants such as NH₃/NF₃, chemical oxide removal, or dry chemical clean may be used. The dielectric material may be recessed to a distance from the surface of the fins 107 of between about 50 Å and about 500 Å, such as about 400 Å. Additionally, the recessing may also remove any leftover dielectric material located over the fins 107 to ensure that the fins 107 are exposed for further processing.

As one of ordinary skill in the art will recognize, however, the steps described above may be only part of the overall process flow used to fill and recess the dielectric material. For example, lining steps, cleaning steps, annealing steps, gap filling steps, combinations of these, and the like may also be utilized to form and fill the first trenches 103 with the dielectric material. All of the potential process steps may be fully intended to be included within the scope of the present embodiment.

After the first isolation regions 105 have been formed, dummy gate dielectrics (not illustrated in FIGS. 1A-1B), dummy gate electrodes (also not illustrated in FIGS. 1A-1B) over the dummy gate dielectrics, and spacers 113 may be formed over each of the fins 107. In an embodiment the dummy gate dielectrics may be formed by thermal oxidation, chemical vapor deposition, sputtering, or any other methods known and used in the art for forming a gate dielectric. Depending on the technique of gate dielectric formation, the dummy gate dielectrics thickness on the top of the fins 107 may be different from the gate dielectric thickness on the sidewall of the fins 107.

The dummy gate dielectrics may comprise a material such as silicon dioxide or silicon oxynitride with a thickness ranging from about 3 Å to about 100 Å, such as about 10 Å. The dummy gate dielectrics may be formed from a high permittivity (high-k) material (e.g., with a relative permittivity greater than about 5) such as lanthanum oxide (La₂O₃), aluminum oxide (Al₂O₃), hafnium oxide (HfO₂), hafnium oxynitride (HfON), or zirconium oxide (ZrO₂), or combinations thereof, with an equivalent oxide thickness of between about 0.5 Å and about 100 Å, such as about 10 Å or less. Additionally, any combination of silicon dioxide, silicon oxynitride, and/or high-k materials may also be used for the dummy gate dielectrics.

The dummy gate electrodes may comprise a conductive or non-conductive material and may be selected from a group comprising polysilicon, W, Al, Cu, AlCu, W, Ti, TiAlN, TaC, TaCN, TaSiN, Mn, Zr, TiN, Ta, TaN, Co, Ni, combinations of these, or the like. The dummy gate electrodes may be deposited by chemical vapor deposition (CVD), sputter deposition, or other techniques known and used in the art for depositing conductive materials. The thickness of the dummy gate electrodes may be in the range of about 5 Å to about 200 Å. The top surface of the dummy gate electrodes may have a non-planar top surface, and may be planarized prior to patterning of the dummy gate electrodes or gate etch. Ions may or may not be introduced into the dummy gate electrodes at this point. Ions may be introduced, for example, by ion implantation techniques.

Once formed, the dummy gate dielectrics and the dummy gate electrodes may be patterned to form a series of dummy stacks over the fins 107. The dummy stacks define multiple channel regions located on each side of the fins 107 beneath the dummy gate dielectrics. The dummy stacks may be formed by depositing and patterning a gate mask (not separately illustrated in FIGS. 1A-1B) on the dummy gate electrodes using, for example, deposition and photolithography techniques known in the art. The gate mask may incorporate commonly used masking and sacrificial materials, such as (but not limited to) silicon oxide, silicon oxynitride, SiCON, SiC, SiOC, and/or silicon nitride and may be deposited to a thickness of between about 5 Å and about 200 Å. The dummy gate electrodes and the dummy gate dielectrics may be etched using a dry etching process to form the patterned in the dummy stacks.

Once the dummy stacks have been patterned, the spacers 113 may be formed. The spacers 113 may be formed on opposing sides of the dummy stacks. The spacers 113 may be formed by blanket depositing one or more spacer layers on the previously formed structure. The one or more spacer layers may comprise SiN, oxynitride, SiC, SiON, SiOCN, SiOC, oxide, and the like and may be formed by methods utilized to form such layers, such as chemical vapor deposition (CVD), plasma enhanced CVD, sputter, and other methods known in the art. In embodiments with more than one spacer layer, the one or more spacer layers may be formed in similar manners using similar materials, but different from one another, such as by comprising materials having different component percentages and with different curing temperatures and porosities. Furthermore, the one or more spacer layers may comprise a different material with different etch characteristics or the same material as the dielectric material within the first isolation regions 105. The one or more spacer layers may then be patterned, such as by one or more etches to remove the one or more spacer layers from the horizontal surfaces of the structure. As such, the one or more spacer layers are formed along sidewalls of the dummy stacks and are collectively referred to as the spacers 113.

In an embodiment, the spacers 113 may be formed to have a thickness of between about 5 Å and about 500 Å. Additionally, once the spacers 113 have been formed, spacers 113 of adjacent stacks of the dummy stacks may be separated from one another by a distance of between about 5 nm and about 200 nm, such as about 20 nm. However, any suitable thicknesses and distances may be utilized.

FIG. 1A further illustrates a removal of the fins 107 from those areas not protected by the dummy stacks and the spacers 113 and a regrowth of source/drain regions 109. The removal of the fins 107 from those areas not protected by the dummy stacks and the spacers 113 may be performed by a reactive ion etch (RIE) using the dummy stacks and the spacers 113 as hard masks, or by any other suitable removal process. The removal may be continued until the fins 107 are either planar with (as illustrated) or below the surface of the first isolation regions 105.

Once these portions of the fins 107 have been removed, a hard mask (not separately illustrated), is placed and patterned to cover the dummy gate electrodes to prevent growth and the source/drain regions 109 may be regrown in contact with each of the fins 107. In an embodiment the source/drain regions 109 may be regrown and, in some embodiments the source/drain regions 109 may be regrown to form a stressor that may impart a stress to the channel regions of the fins 107 located underneath the dummy stacks. In an embodiment wherein the fins 107 comprise silicon and the FinFET is a p-type device, the source/drain regions 109 may be regrown through a selective epitaxial process with a material, such as silicon or else a material such as silicon germanium that has a different lattice constant than the channel regions. The epitaxial growth process may use precursors such as silane, dichlorosilane, germane, and the like, and may continue for between about 5 minutes and about 120 minutes, such as about 30 minutes.

In an embodiment the source/drain regions 109 may be formed to have a thickness of between about 5 Å and about 1000 Å and a height over the first isolation regions 105 of between about 10 Å and about 500 Å, such as about 200 Å. In this embodiment, the source/drain regions 109 may be formed to have a height above the upper surface of the first isolation regions 105 of between about 5 nm and about 250 nm, such as about 100 nm. However, any suitable height may be utilized.

Once the source/drain regions 109 are formed, dopants may be implanted into the source/drain regions 109 by implanting appropriate dopants to complement the dopants in the fins 107. For example, p-type dopants such as boron, gallium, indium, or the like may be implanted to form a PMOS device. Alternatively, n-type dopants such as phosphorous, arsenic, antimony, or the like may be implanted to form an NMOS device. These dopants may be implanted using the dummy stacks and the spacers 113 as masks. It should be noted that one of ordinary skill in the art will realize that many other processes, steps, or the like may be used to implant the dopants. For example, one of ordinary skill in the art will realize that a plurality of implants may be performed using various combinations of spacers and liners to form source/drain regions having a specific shape or characteristic suitable for a particular purpose. Any of these processes may be used to implant the dopants, and the above description is not meant to limit the present embodiments to the steps presented above.

Additionally at this point the hard mask that covered the dummy gate electrodes during the formation of the source/drain regions 109 is removed. In an embodiment the hard mask may be removed using, e.g., a wet or dry etching process that is selective to the material of the hard mask. However, any suitable removal process may be utilized.

FIG. 1A also illustrates a formation of a first interlayer dielectric (ILD) layer 111 (illustrated in dashed lines in FIG. 1A in order to more clearly illustrate the underlying structures) over the dummy stacks and the source/drain regions 109. The first ILD layer 111 may comprise a material such as boron phosphorous silicate glass (BPSG), although any suitable dielectrics may be used. The first ILD layer 111 may be formed using a process such as PECVD, although other processes, such as LPCVD, may alternatively be used. The first ILD layer 111 may be formed to a thickness of between about 100 Å and about 3,000 Å. Once formed, the first ILD layer 111 may be planarized with the spacers 113 using, e.g., a planarization process such as chemical mechanical polishing process, although any suitable process may be utilized.

Once the first ILD layer 111 has been formed, the dummy gate electrode and the dummy gate dielectric are removed. In an embodiment, the dummy gate electrodes and the dummy gate dielectrics may be removed using, e.g., one or more wet or dry etching processes that utilize etchants that are selective to the materials of the dummy gate electrodes and the dummy gate dielectrics. However, any suitable removal process or processes may be utilized.

Once the dummy gate electrodes and the dummy gate dielectrics have been removed, a plurality of layers for gate stacks are deposited in their stead, including a first dielectric material, a first conductive layer, a first metal material, a work function layer, and a first barrier layer. In an embodiment the first dielectric material is a high-k material such as HfO₂, HfSiO, HfSiON, HfTaO, HfTiO, HfZrO, LaO, ZrO, Ta₂O₅, combinations of these, or the like, deposited through a process such as atomic layer deposition, chemical vapor deposition, or the like. The first dielectric material may be deposited to a thickness of between about 5 Å and about 200 Å, although any suitable material and thickness may be utilized.

Optionally, an interfacial layer may be formed prior to the formation of the first dielectric material. In an embodiment the interfacial layer may be a material such as silicon dioxide formed through a process such as in situ steam generation (ISSG). However, any suitable material or process of formation may be utilized.

The first conductive layer may be a metal silicide material such as titanium silicon nitride (TSN). In an embodiment the first conductive layer may be formed using a deposition process such as chemical vapor deposition, although any suitable method of deposition, such as a deposition and subsequent silicidation, may be utilized to a thickness of between about 5 Å and about 30 Å. However, any suitable thickness may be utilized.

The first metal material may be formed adjacent to the first dielectric material as a barrier layer and may be formed from a metallic material such as TaN, Ti, TiAlN, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The first metal material may be deposited using a deposition process such as atomic layer deposition, chemical vapor deposition, sputtering, or the like, to a thickness of between about 5 Å and about 200 Å, although any suitable deposition process or thickness may be used.

The work function layer is formed over the first metal material, and the material for the work function layer may be chosen based upon the type of device desired. Exemplary p-type work function metals that may be included include Al, TiAlC, TiN, TaN, Ru, Mo, WN, ZrSi₂, MoSi₂, TaSi₂, NiSi₂, WN, other suitable p-type work function materials, or combinations thereof. Exemplary n-type work function metals that may be included include Ti, Ag, TaAl, TaAlC, TiAlN, TaC, TaCN, TaSiN, Mn, Zr, other suitable n-type work function materials, or combinations thereof. A work function value is associated with the material composition of the work function layer, and thus, the material of the work function layer is chosen to tune its work function value so that a desired threshold voltage Vt is achieved in the device that is to be formed in the respective region. The work function layer(s) may be deposited by CVD, PVD, and/or other suitable process to a thickness of between about 5 Å and about 50 Å.

The first barrier layer may be formed adjacent to the work function layer and, in a particular embodiment, may be similar to the first metal material. For example, the first barrier layer may be formed from a metallic material such as TiN, Ti, TiAlN, TaC, TaCN, TaSiN, Mn, Zr, TaN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the first barrier layer may be deposited using a deposition process such as atomic layer deposition, chemical vapor deposition, sputtering, or the like, to a thickness of between about 5 Å and about 200 Å, although any suitable deposition process or thickness may be used.

The metal layer may be a material that is both suitable for use as a seed layer to help a subsequent filling process as well as a material that can be used to help block or reduce the transport of fluorine atoms into the work function layer. In a particular embodiment, the metal layer may be crystalline tungsten (W) that is formed free from the presence of fluorine atoms using, e.g., an atomic layer deposition process, although any suitable deposition process may be utilized. The metal layer may be formed to a thickness of between about 20 Å and about 50 Å, such as between about 30 Å and about 40 Å.

Once the metal layer has been formed, a fill material is deposited to fill a remainder of the opening. In an embodiment the fill material may be a material such as Al, Cu, AlCu, W, Ti, TiAlN, TaC, TaCN, TaSiN, Mn, Zr, TiN, Ta, TaN, Co, Ni, combinations of these, or the like, to a thickness of between about 1000 Å and about 2000 Å, such as about 1500 Å. However, any suitable material may be utilized.

After the fill material has been deposited to fill and overfill the openings, the materials of the first dielectric material, first conductive layer, first metal material, work function layer, first barrier layer, metal layer, and fill material may be planarized to form a gate stack 115. In an embodiment the materials may be planarized with the first ILD layer 111 using, e.g., a chemical mechanical polishing process, although any suitable process, such as grinding or etching, may be utilized. Additionally, after the planarization the gate stack 115 may have a bottom width of between about 10 nm and about 13 nm, although any suitable dimensions may be utilized.

FIGS. 1A-1B further illustrates a recessing of the gate stacks 115. After the materials of the gate stacks 115 have been formed and planarized, the materials of the gate stacks 115 may be recessed using an etch back process that utilizes etchants selective to the materials of the gate stacks 115. The etch back process may be a wet or dry etching process utilizing etchants selective to the materials of the gate stacks 115. In some embodiments the materials of the gate stacks 115 may be recessed a first distance of between about 5 nm and about 150 nm, such as about 120 nm. However, any suitable etching process using any suitable etchants and any suitable distances may be utilized. Additionally, during the etch back process a portion of the spacers 113 may also be removed below a level of the first ILD layer 111.

Once the gate stacks 115 have been recessed, a first metal layer 117 and a first hard mask layer 119 may be deposited. Once the materials of the gate stack 115 have been recessed, the first metal layer 117 (e.g., capping layer) is deposited in order to act as an etch stop layer for subsequent processing (described further below). In an embodiment the first metal layer 117 is a metal material such as tungsten (W), cobalt (Co), molybdenum (Mo), titanium nitride (TiN), ruthenium (Ru), aluminum (Al), zirconium (Zr), gold (Au), platinum (Pt), copper (Cu), alloys of these metal materials, and the like and is formed using, e.g., an atomic layer deposition process which may selectively grow on the material of the gate stack 115 without forming on other exposed surfaces. The first metal layer 117 may be formed to a thickness of between about 1 nm and about 10 nm. However, any suitable material, process of formation, and thickness may be utilized.

In an embodiment the first hard mask layer 119 is a material with a high etch selectivity to other materials used to form the gate stack 115, the first metal layer 117, the first ILD layer 111, and the spacers 113. In a particular embodiment the first hard mask layer 119 may be a material such as lanthanum oxide, aluminum oxide, ytterbium oxide, tantalum carbon nitride, (TaCN), zirconium silicon (ZrSi), silicon oxycarbonitride (SiOCN), silicon oxycarbice (SiOC), silicon carbonitride (SiCN), zirconium nitride (ZrN), zirconium aluminum oxide (ZrAlO), titanium oxide (TiO), tantalum oxide (TaO), zirconium oxide (ZrO), hafnium oxide (HfO), silicon nitride (SiN), hafnium silicon (HfSi), aluminum oxynitride (AlON), silicon carbide (SiC), combinations of these, or the like, may also be utilized. The first hard mask layer 119 may be deposited using a deposition process such as plasma enhanced atomic layer deposition (PEALD), thermal atomic layer deposition (thermal ALD), plasma enhanced chemical vapor deposition (PECVD). However, any suitable deposition process and process conditions may be utilized.

Once the first hard mask layer 119 has been deposited, the first hard mask layer 119 may be planarized to remove excess material. In an embodiment the first hard mask layer 119 may be planarized using, e.g., a chemical mechanical polishing process, whereby etchants and abrasives are utilized along with a rotating platen in order to react and remove the excess material of the first hard mask layer 119. However, any suitable planarization process may be utilized to planarize the first hard mask layer 119 and the first ILD layer 111.

Once the first hard mask layer 119 has been planarized, the first hard mask layer 119 may have a first roof thickness T₁ of between about 1 nm and about 30 nm and have a second bottom portion thickness T₂ of between about 1 nm and about 50 nm. Finally, the first hard mask layer 119 may have a first width W₁ of between about 2 nm and about 50 nm. However, any suitable thicknesses may be utilized.

Turning now to FIG. 1B (which illustrates a cross-sectional view of the structure in FIG. 1A with additional gate stacks 115 and source/drain regions 109 along a single fin 107), FIG. 1B illustrates formation of source/drain contacts 121 through the first ILD layer 111 to make contact to some of the source/drain regions 109 (with similar contacts being formed to other source/drain regions along different cross-sections). In an embodiment the source/drain contacts 121 may be formed by initially forming openings through the first ILD layer 111 using, e.g. a masking and etching process. Once the source/drain regions 109 have been exposed, an optional silicide contact (not separately illustrated) may be formed on the source/drain regions 109. The optional silicide contact may comprise titanium (e.g., titanium silicide (TiSi)) in order to reduce the Schottky barrier height of the contact. However, other metals, such as nickel, cobalt, erbium, platinum, palladium, and the like, may also be used. A silicidation may be performed by blanket deposition of an appropriate metal layer, followed by an annealing step which causes the metal to react with the underlying exposed silicon of the source/drain regions 109. Un-reacted metal is then removed, such as with a selective etch process. The thickness of the optional silicide contact may be between about 5 nm and about 50 nm.

FIG. 1B also illustrates a formation of a remainder of the source/drain contacts 121 in physical connection with the optional silicide contact (when present) or the source/drain regions 109. In an embodiment the source/drain contacts 121 may be a conductive material such as W, Al, Cu, AlCu, W, Co, TaC, TaCN, TaSiN, Mn, Zr, TiN, Ta, TaN, Ni, Ti, TiAlN, Ru, Mo, or WN, although any suitable material, such as aluminum, copper, alloys of these, combinations of these, or the like, and may be deposited using a deposition process such as sputtering, chemical vapor deposition, electroplating, electroless plating, or the like, to fill and/or overfill the opening within the first ILD layer 111.

Once the material for the source/drain contacts 121 has been deposited, the material for the source/drain contacts 121 may be planarized with the first ILD layer 111. In an embodiment the material of the source/drain contacts 121 may be planarized using, e.g., a chemical mechanical polishing process, whereby etchants and abrasives are utilized along with a rotating platen in order to react and remove the excess material of the source/drain contacts 121. However, any suitable planarization process may be utilized to planarize the source/drain contacts 121.

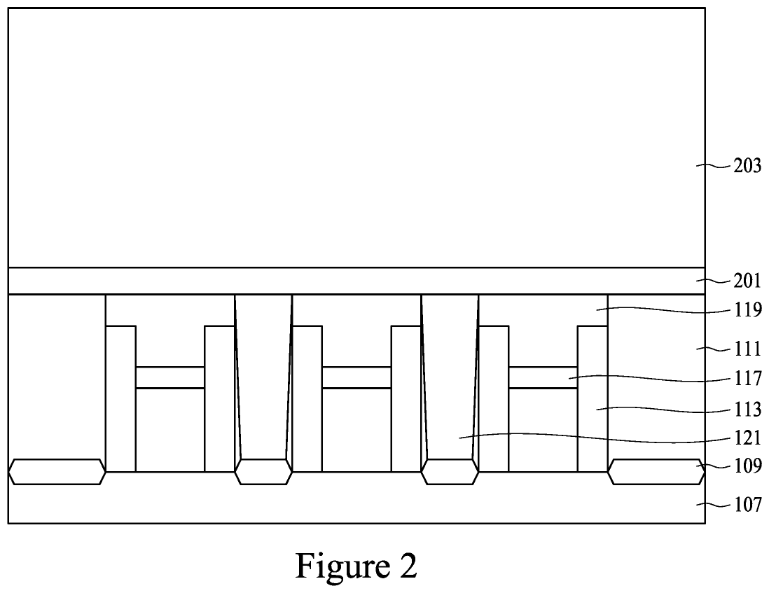

FIG. 2 illustrates a formation of a CESL 201 and a second ILD layer 203 over the planarized surfaces. In an embodiment the contact etch stop layer (CESL) 201 may be formed as a single layer or may be formed as a plurality of etch stop layers using materials such as lanthanum oxide, aluminum oxide, ytterbium oxide, tantalum carbon nitride, (TaCN), zirconium silicon (ZrSi), silicon oxycarbonitride (SiOCN), silicon oxycarbice (SiOC), silicon carbonitride (SiCN), zirconium nitride (ZrN), zirconium aluminum oxide (ZrAlO), titanium oxide (TiO), tantalum oxide (TaO), zirconium oxide (ZrO), hafnium oxide (HfO), silicon nitride (SiN), hafnium silicon (HfSi), aluminum oxynitride (AlON), silicon oxide (SiO), silicon carbide (SiC), combinations of these, or the like, and may be blanket deposited and/or conformally deposited. The CESL 201 may be deposited using one or more low temperature deposition processes such as chemical vapor deposition, physical vapor deposition, or atomic layer deposition. The CESL 201 may be deposited to an overall thickness of between about 10 Å and about 150 Å, such as about 70 Å, in accordance with some embodiments. However, any suitable etch stop materials, any suitable number of etch stop layers, and any suitable combinations thereof may be deposited to form the CESL 201.

Once the CESL 201 has been formed, the second ILD layer 203 is deposited over the CESL 201. The second ILD layer 203 may be formed of a dielectric material such as lanthanum oxide, aluminum oxide, ytterbium oxide, tantalum carbon nitride, (TaCN), zirconium silicon (ZrSi), silicon oxycarbonitride (SiOCN), silicon oxycarbice (SiOC), silicon carbonitride (SiCN), zirconium nitride (ZrN), zirconium aluminum oxide (ZrAlO), titanium oxide (TiO), tantalum oxide (TaO), zirconium oxide (ZrO), hafnium oxide (HfO), silicon nitride (SiN), hafnium silicon (HfSi), aluminum oxynitride (AlON), silicon oxide (SiO), silicon carbide (SiC), combinations of these, or the like, formed by any acceptable process (e.g., CVD, PEALD, thermal ALD, PECVD, or the like). However, other suitable insulation materials (e.g., PSG, BSG, BPSG, USG, or the like) deposited by any suitable method (e.g., CVD, PECVD, flowable CVD, or the like) may also be used. After formation, the second ILD layer 203 may be cured, such as by an ultraviolet curing process, and then planarized using, e.g., a planarization process such as a chemical mechanical polishing process; although, any suitable process may be utilized. As such, the second ILD layer 203 may be formed to a thickness of between about 5 nm and about 20 nm, such as about 13 nm. However, any suitable thickness may be utilized.

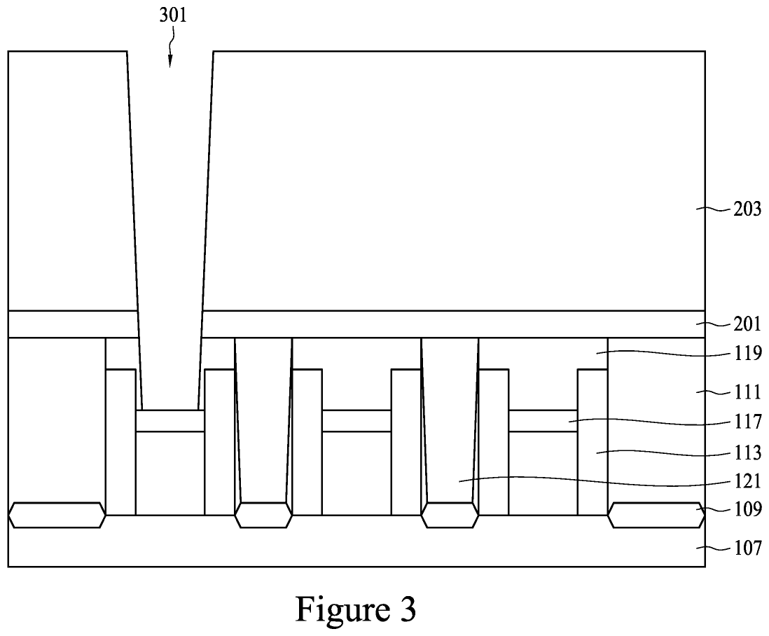

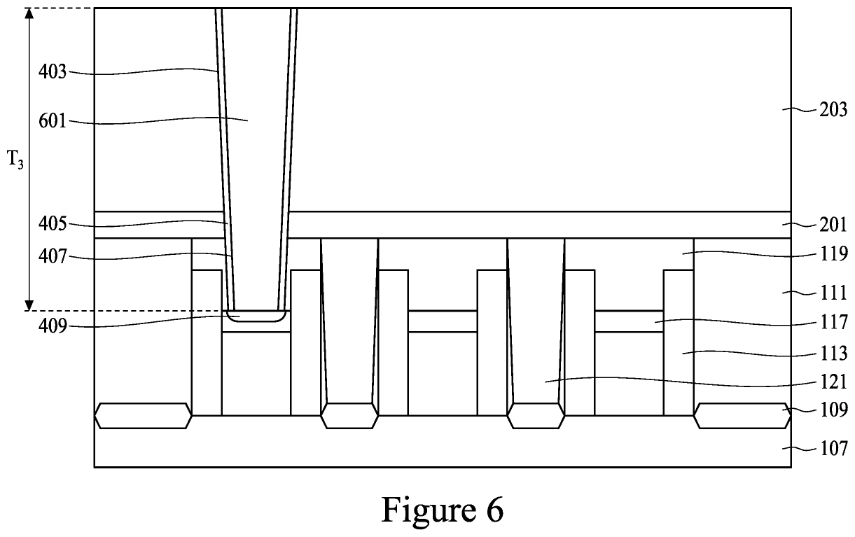

FIG. 3 illustrates that, once the second ILD layer 203 has been formed and planarized, contact via openings 301 (with a single contact via opening 301 being shown in FIG. 3 for illustration but wherein a plurality of contact via openings 301 may be formed in one die) for the gate via contact 601 (not illustrated in FIG. 3 but illustrated and described further below with respect to FIG. 6) are formed through the second ILD layer 203 using one or more etching processes to form the contact via openings 301. According to some embodiments, the contact via openings 301 are formed through the second ILD layer 203, the CESL 201, and the first hard mask layer 119. The contact via openings 301 may be formed using any combination of acceptable photolithography and suitable etching techniques such as dry etching process (e.g., plasma etch, reactive ion etch (RIE), physical etching (e.g., ion beam etch (IBE))), wet etching, combinations thereof, and the like.

In particular embodiments the contact via openings 301 may be formed to have a high aspect ratio. For example, the contact via openings 301 may have an aspect ratio of between about 5 and about 8. However, any suitable aspect ratios and any suitable dimensions may be utilized.

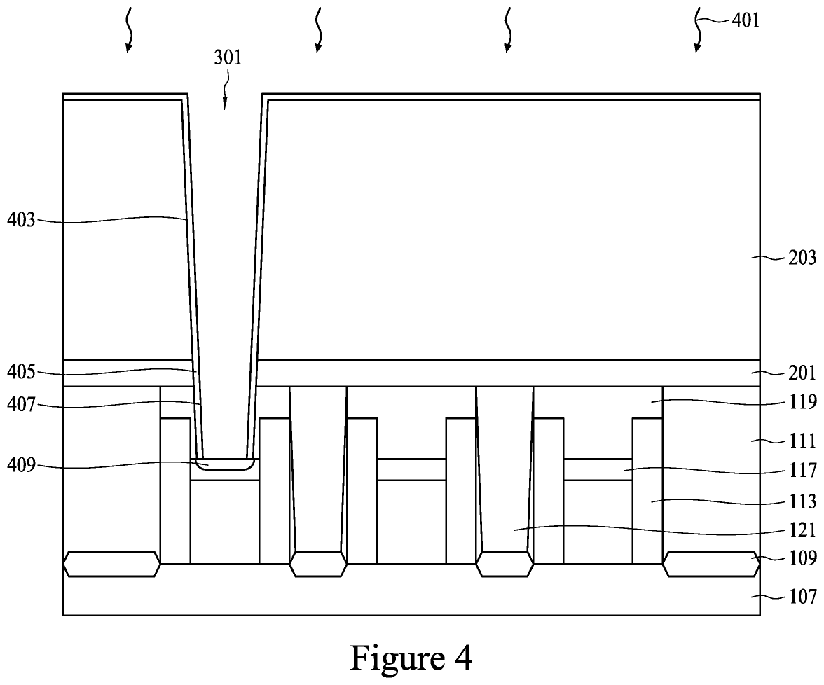

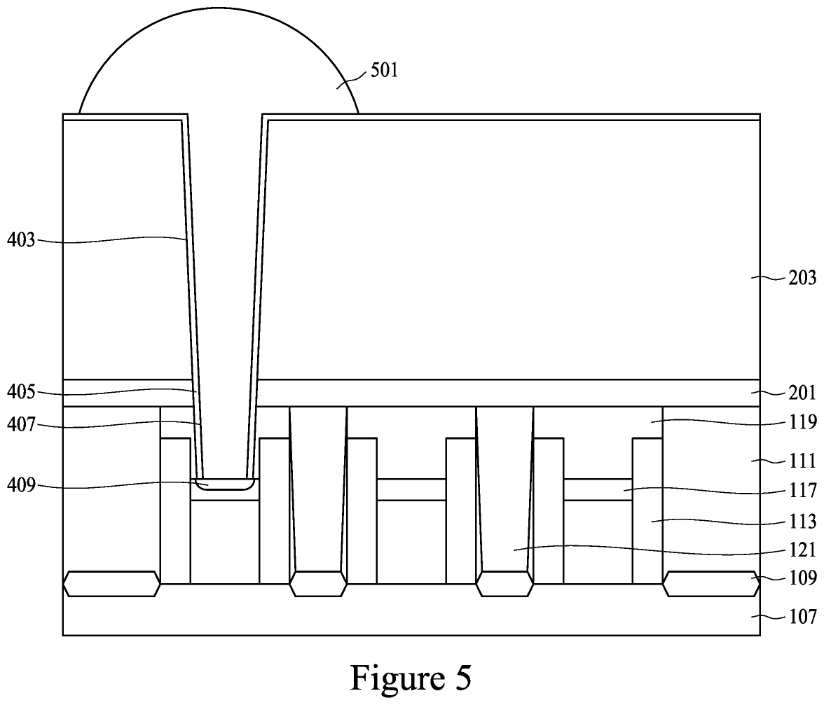

FIG. 4 illustrates the use of a first treatment (represented in FIG. 4 by the curved lines labeled 401), such as a NH₃ treatment, in order to treat the exposed sidewalls of the second ILD layer 203, the CESL 201, the first hard mask layer 119, and the exposed portion of the first metal layer 117 for inhibiting metal growth on dielectric sidewalls. In an embodiment the first treatment 401 may be used to implant or react one or more dopants that help inhibit the growth of a subsequently deposited conductive material 501 (not illustrated in FIG. 4 but illustrated and further discussed below with respect to FIG. 5) within the contact via openings 301. In some embodiments the dopants may be nitrogen, hydrogen, combinations of these, or the like. However, any suitable dopant or dopants may be utilized.

In an embodiment the dopants may be implanted or reacted with the exposed materials using, e.g., a plasma process that utilizes a dopant-containing precursor. For example, in an embodiment in which the dopant is nitrogen, the dopant-containing precursor may be a nitrogen containing precursor such as ammonia (NH₃), N₂, combinations of these, or the like. However, any suitable precursor may be utilized.

To initiate the first treatment 401, a flow rate of the dopant containing precursor can be set to be in a range from about 10 sccm to about 1,000 sccm. The dopant containing precursor may be ignited into a plasma using, e.g., a transformer coupled plasma generator, an inductively coupled plasma system, a remote plasma generator, or the like using a power between about 50 W to about 500 W, wherein a frequency of the plasma generator can be about 13.56 MHz or greater. Additionally, the first treatment 401 may be performed at pressure in a range from about 0.5 Torr to about 10 Torr. The temperature of the first treatment 401 can be set to be in a range from about 250° C. to about 450° C. However, any suitable process parameters may be utilized.

During the first treatment 401, the dopants (e.g., nitrogen) may diffuse into and react with the material of the second ILD layer 203. This diffusion and reaction may cause the formation of a first treated layer 403 along the sidewalls and top of the second ILD layer 203. For example, in an embodiment in which the second ILD layer 203 is lanthanum oxide, the first treated layer 403 may be lanthanum oxynitride. However, any suitable material may be utilized.

Once formed, the first treated layer 403 may have a thickness of between about 2 Å and about 50 Å. Additionally, the first treated layer 403 may have a decreasing concentration of the dopants (e.g., nitrogen) from the exposed surface, with a concentration of the dopant at the exposed surface being between about 0.3%-atomic and about 3%-atomic. However, any suitable concentration may be utilized.

Additionally during the first treatment 401, the dopants (e.g., nitrogen) will also diffuse into and react with the material of the CESL 201. This diffusion and reaction will cause the formation of a second treated layer 405 along the sidewalls of the CESL 201. For example, in an embodiment in which the CESL 201 is aluminum oxide, the second treated layer 405 will be aluminum oxynitride. However, any suitable material may be utilized.

Once formed, the second treated layer 405 will have a thickness of between about 2 Å and about 50 Å. Additionally, the second treated layer 405 will have a decreasing concentration of the dopants (e.g., nitrogen) from the exposed surface, with a concentration of the dopant at the exposed surface being between about 0.3%-atomic and about 3%-atomic. However, any suitable concentration may be utilized.

The first treatment 401 will additionally cause the dopants (e.g., nitrogen) to diffuse into and react with the material of the first hard mask layer 119. This diffusion and reaction will cause the formation of a third treated layer 407 along the sidewalls of the first hard mask layer. For example, in an embodiment in which the first hard mask layer is yttrium oxide, the second treated layer 405 will be yttrium oxynitride. However, any suitable material may be utilized.

Once formed, the third treated layer 407 will have a thickness of between about 2 Å and about 50 Å. Additionally, the third treated layer 407 will have a decreasing concentration of the dopants (e.g., nitrogen) from the exposed surface, with a concentration of the dopant at the exposed surface being between about 0.3%-atomic and about 3%-atomic. However, any suitable concentration may be utilized.

Finally, the first treatment 401 may cause the dopants (e.g., nitrogen) to diffuse into and react with the material of the first metal layer 117. This diffusion and reaction may cause the formation of a fourth treated layer 409 along the exposed surface of the first metal layer 117. For example, in an embodiment in which the first metal layer is tungsten, the fourth treated layer 409 may be tungsten nitride. However, any suitable material may be utilized.

Once formed, the fourth treated layer 409 may have a thickness that is greater than the thicknesses of the treated dielectric layers. In a particular embodiment the fourth treated layer 409 may have a thickness that is 0 nm to 70 nm greater than the thicknesses of the treated dielectric layers, such as having a thickness of between about 5 Å and about 120 Å. Additionally, the fourth treated layer 409 may have a decreasing concentration of the dopants (e.g., nitrogen) from the exposed surface, with a concentration of the dopant at the exposed surface being between about 1%-atomic and about 30%-atomic. However, any suitable concentration may be utilized.

FIG. 5 illustrates that, once the treatment has been performed, the contact via openings 301 may be filled or overfilled with one or more conductive materials 501, such that the one or more conductive materials 501 are in direct physical contact with the first treated layer 403, the second treated layer 405, the third treated layer 407, and the fourth treated layer 409 without an intervening liner. According to embodiments, the conductive material may be a high-performance, low resistance material such as tungsten, ruthenium, molybdenum, copper, titanium, titanium nitride, cobalt, aluminum, combinations of these, or the like. The one or more conductive materials 501 may be deposited using a chemical vapor deposition process with precursors that may or may not have bottom-up filling capabilities. For example, in an embodiment in which non-bottom up precursors are utilized, precursors such as Ru(CO)₁₂ (when depositing ruthenium), W(CO)6 (when depositing tungsten), MoO₂Cl₂ (when depositing molybdenum) may be used. However, any other suitable method, such as a selective, bottom-up deposition process such as electroplating, electroless, plating, combinations of these, or the like, may also be used.

In embodiments in which chemical vapor deposition is utilized to deposit the material of the one or more conductive materials 501, the presence of the first treated layer 403, the second treated layer 405, and the third treated layer 407 work to restrict the ability of the chemical vapor deposition process to deposit material along the sidewalls of the dielectric materials (e.g., the first hard mask layer 119, the CESL 201, and the second ILD layer 203) and to form larger as deposited grains. In particular, the presence of the dopants works to limit the ability of the conductive material to nucleate along the sidewalls without significantly limiting the ability of the conductive material to nucleate and grow along the bottom. As such, in embodiments in which non-bottom-up precursors are utilized, a more bottom-up deposition process can be achieved without having to rely upon a more restricted list of potential precursors. In other words, a psuedo-bottom up deposition process can be achieved without the use of bottom-up precursors. With a larger, more bottom-up process, pinch-offs are less likely to occur, meaning fewer and/or smaller voids (or even no voids at all) being formed, thereby allowing for the use of higher performance (e.g., lower resistance) materials for the one or more conductive materials 501.

FIG. 6 illustrates that, once the one or more conductive materials 501 have been deposited, a planarization process, such as a CMP, may be performed to remove excess material from a surface of the second ILD layer 203. The remaining conductive material forms the source/drain via contact 601 in the openings, and the source/drain via contact 601 may have a third thickness T₃ of between about 5 nm and about 40 nm. However, any suitable thickness may be utilized.

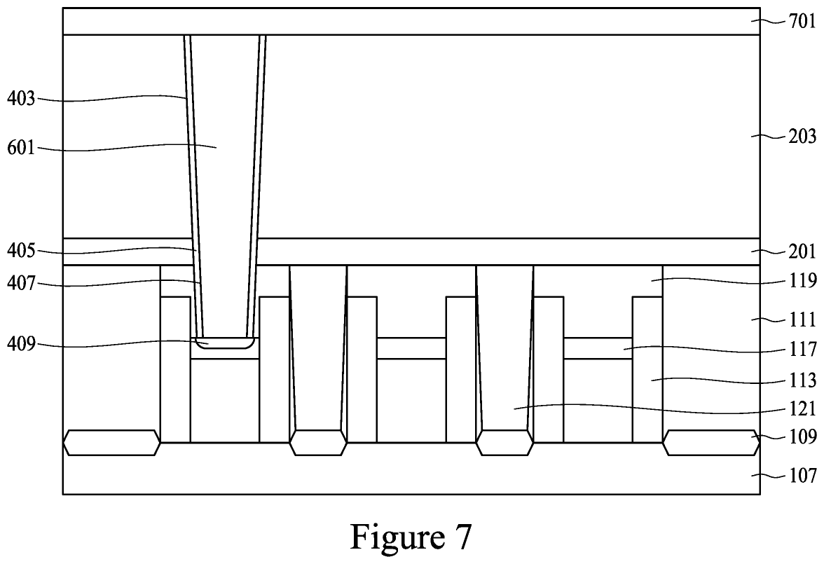

FIG. 7 illustrates formation of a dielectric recap 701 over the gate via contact 601. In an embodiment the formation of the dielectric recap 701 includes a filling step to fill any undesired recesses (not seen in this particular cross-section but which may be present at different point over the substrate 101), and then a planarization step is performed to planarize the top surface of dielectric recap 701. In accordance with some embodiments, the dielectric recap 701 comprises silicon oxide, although any suitable material may be utilized, and may be deposited using chemical vapor deposition, atomic layer deposition, physical vapor deposition, combinations of these, or the like. However, any suitable method of deposition and/or planarization may be utilized.

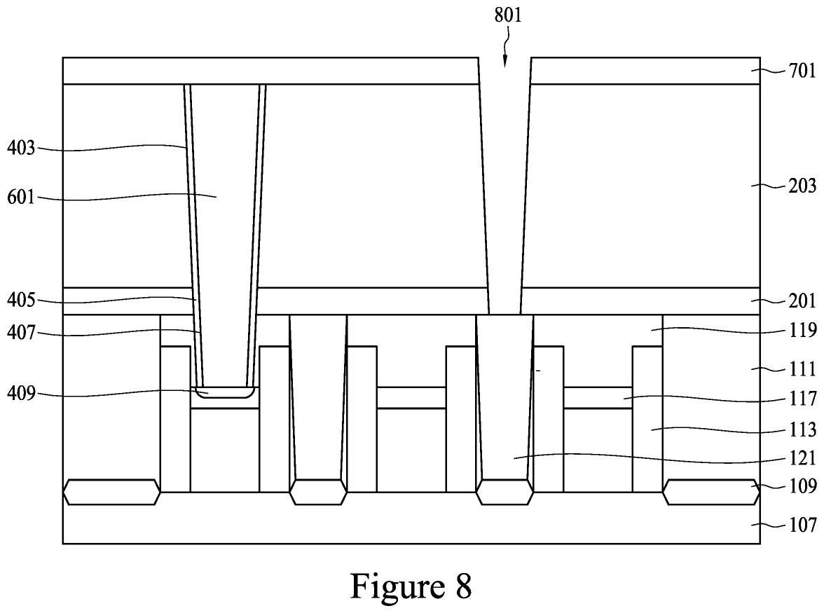

FIG. 8 illustrates formation of source/drain contact openings 801. In an embodiment the source/drain contact openings 801 may be formed using one or more etching processes to form the source/drain contact openings 801. According to some embodiments, the source/drain contact openings 801 are formed through the second ILD layer 203 and the CESL 201. The source/drain contact openings 801 may be formed using any combination of acceptable photolithography and suitable etching techniques such as dry etching process (e.g., plasma etch, reactive ion etch (RIE), physical etching (e.g., ion beam etch (IBE))), wet etching, combinations thereof, and the like. However, any suitable etching processes may be utilized to form the source/drain contact openings 801.

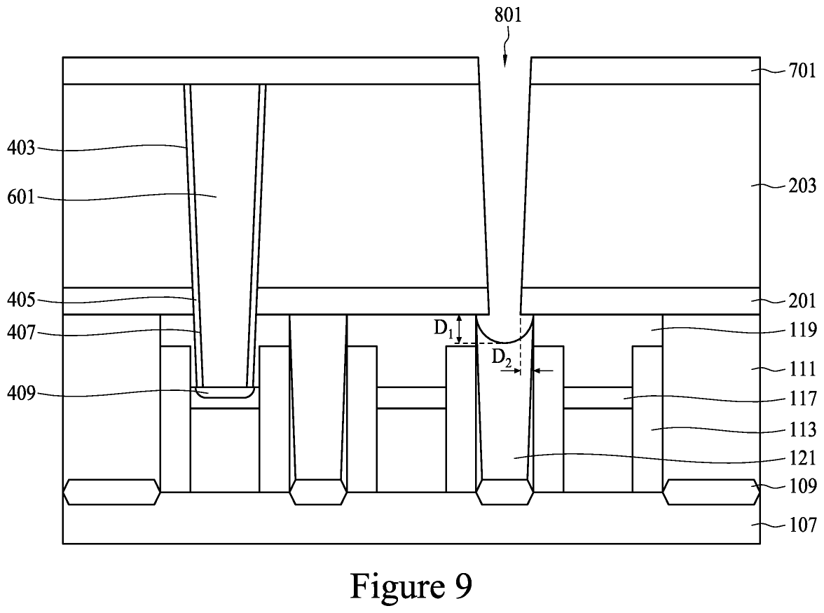

FIG. 9 illustrates a recessing process that may be used to extend the source/drain contact openings 801 into the material of the source/drain contacts 121. In an embodiment the extending of the source/drain contact openings 801 may be performed using an isotropic etching process, such as a wet etch, or an anisotropic etching process, such as a reactive ion etching process, using one or more etchants that is selective to the material of the source/drain contacts 121.

In embodiments in which an isotropic etching process is utilized to recess the material of the source/drain contacts 121, the recess may extend the source/drain contact openings 801 both into the material of the source/drain contact openings 801 and also beneath the CESL 201. For example, the recessing may extend the source/drain contact openings 801 a first distance D₁ into the material of the source/drain contact openings 801 of between about 2 nm and about 20 nm, and also extend the source/drain contact openings 801 a second distance D₂ under the CESL 201 of between about 1 nm and about 10 nm. In some embodiments the second distance D₂ may be enough to expose sidewalls of the first hard mask layer 119, although in other embodiments the first hard mask layer 119 is not exposed.

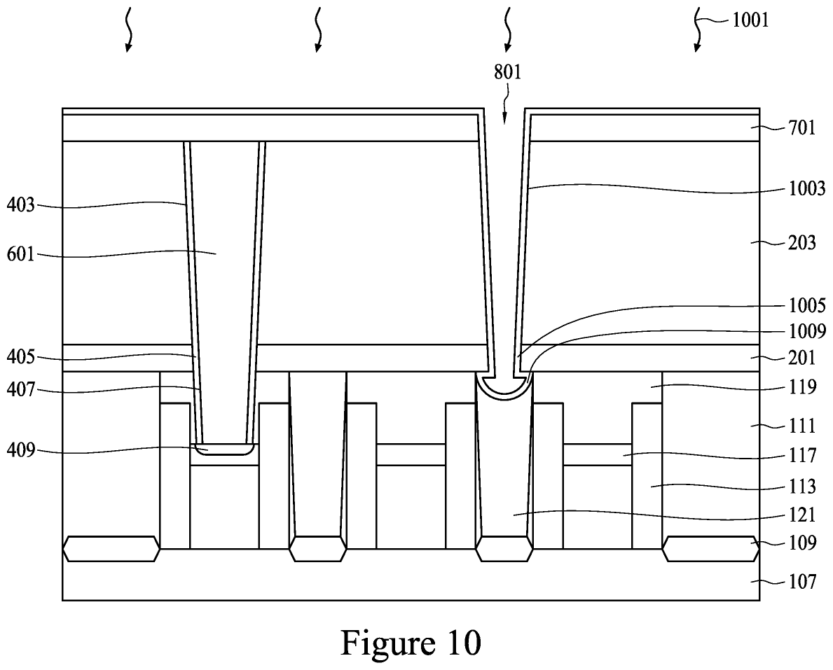

FIG. 10 illustrates that, once the source/drain contact openings 801 have been formed, a second treatment (represented in FIG. 10 by the arrows labeled 1001) may be performed on the exposed surfaces of the second ILD layer 203, the CESL 201, the source/drain contacts 121, and, if exposed, the first hard mask layer 119. In an embodiment the second treatment 1001 may be performed using similar processes and parameters as described above with respect to the first treatment 401. For example, the second treatment 1001 may be a plasma treatment that utilizes ammonia as a precursor to treat the exposed surfaces with nitrogen. However, any suitable processes and parameters may be utilized.

During the second treatment 1001, the dopants (e.g., nitrogen) may diffuse into and react with the material of the second ILD layer 203. This diffusion and reaction may cause the formation of a fifth treated layer 1003 along the sidewalls of the second ILD layer 203 in the source/drain contact openings 801. For example, in an embodiment in which the second ILD layer 203 is lanthanum oxide, the fifth treated layer 1003 may be lanthanum oxynitride. However, any suitable material may be utilized.

Once formed, the fifth treated layer 1003 may have a thickness of between about 2 Å and about 50 Å. Additionally, the fifth treated layer 1003 may have a decreasing concentration of the dopants (e.g., nitrogen) from the exposed surface, with a concentration of the dopant at the exposed surface being between about 0.3%-atomic and about 3%-atomic. However, any suitable concentration may be utilized.

Additionally during the second treatment 1001, the dopants (e.g., nitrogen) may diffuse into and react with the material of the CESL 201 in the source/drain contact openings 801. This diffusion and reaction may cause the formation of a sixth treated layer 1005 along the sidewalls of the CESL 201. For example, in an embodiment in which the CESL 201 is aluminum oxide, the sixth treated layer 1005 may be aluminum oxynitride. However, any suitable material may be utilized.

Once formed, the sixth treated layer 1005 may have a thickness of between about 2 Å and about 50 Å. Additionally, the sixth treated layer 1005 may have a decreasing concentration of the dopants (e.g., nitrogen) from the exposed surface, with a concentration of the dopant at the exposed surface being between about 0.3%-atomic and about 3%-atomic. However, any suitable concentration may be utilized.

The second treatment 1001 may also (if the first hard mask layer 119 is exposed during the recessing) additionally cause the dopants (e.g., nitrogen) to diffuse into and react with the material of the first hard mask layer 119. This diffusion and reaction may cause the formation of a seventh treated layer (not separately illustrated in FIG. 10) along the sidewalls of the first hard mask layer 119. For example, in an embodiment in which the first hard mask layer 119 is yttrium oxide, the seventh treated layer may be yttrium oxynitride. However, any suitable material may be utilized.

Once formed, the seventh treated layer may have a thickness of between about 2 Å and about 50 Å. Additionally, the third treated layer 407 may have a decreasing concentration of the dopants (e.g., nitrogen) from the exposed surface, with a concentration of the dopant at the exposed surface being between about 0.3%-atomic and about 3%-atomic. However, any suitable concentration may be utilized.

Finally, the second treatment 1001 may cause the dopants (e.g., nitrogen) to diffuse into and react with the material of the source/drain contacts 121. This diffusion and reaction may cause the formation of an eighth treated layer 1009 along the exposed surface of the source/drain contacts 121. For example, in an embodiment in which the source/drain contacts 121 is tungsten, the eighth treated layer 1009 may be tungsten nitride. However, any suitable material may be utilized.

Once formed, the eighth treated layer 1009 may have a thickness that is larger than the thickness of the treated dielectric layers. For example the eighth treated layer 1009 may have a thickness that is 0 nm to 70 nm greater than the treated dielectric layer (e.g., the treated second ILD layer 203 and the treated CESL 201), such as a thickness of between about 5 Å and about 120 Å. Additionally, the fourth treated layer 409 may have a decreasing concentration of the dopants (e.g., nitrogen) from the exposed surface, with a concentration of the dopant at the exposed surface being between about 1%-atomic and about 30%-atomic. However, any suitable concentration may be utilized.

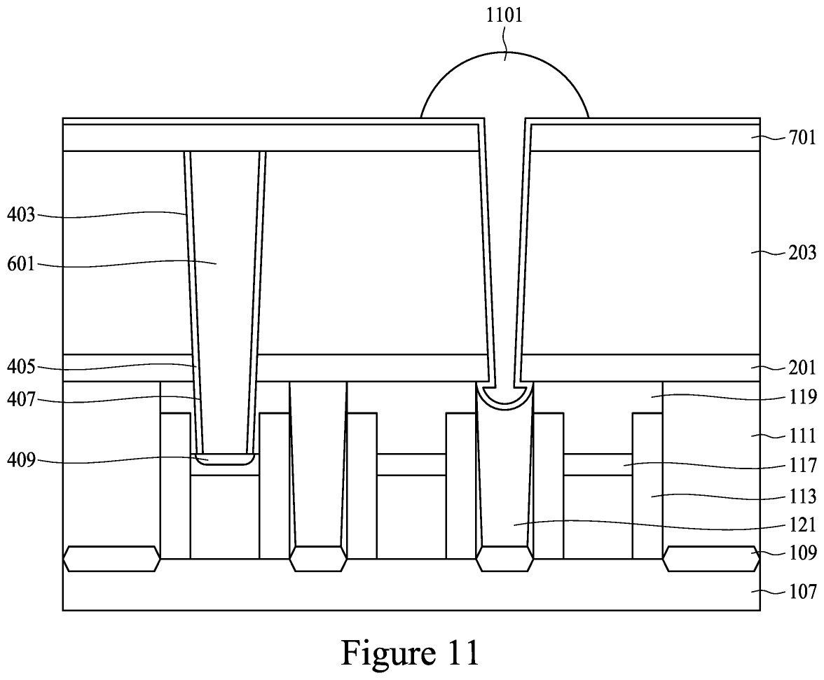

FIG. 11 illustrates that, once the second treatment 1001 has been performed, a one or more via drain contact materials 1101 is deposited to fill and/or overfill the source/drain contact openings 801. In an embodiment the one or more via drain contact materials 1101 may be deposited using similar methods and materials as the one or more conductive materials 501 (described above with respect to FIG. 5). However, any suitable materials and methods may be utilized.

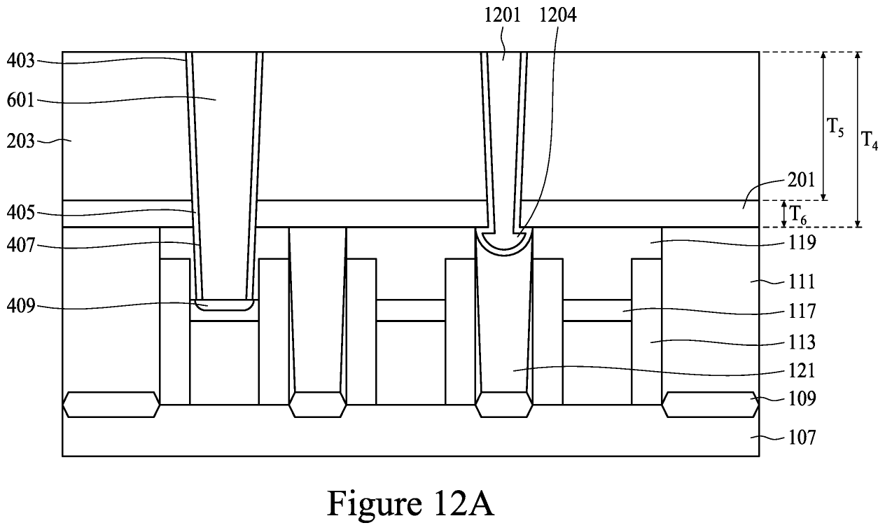

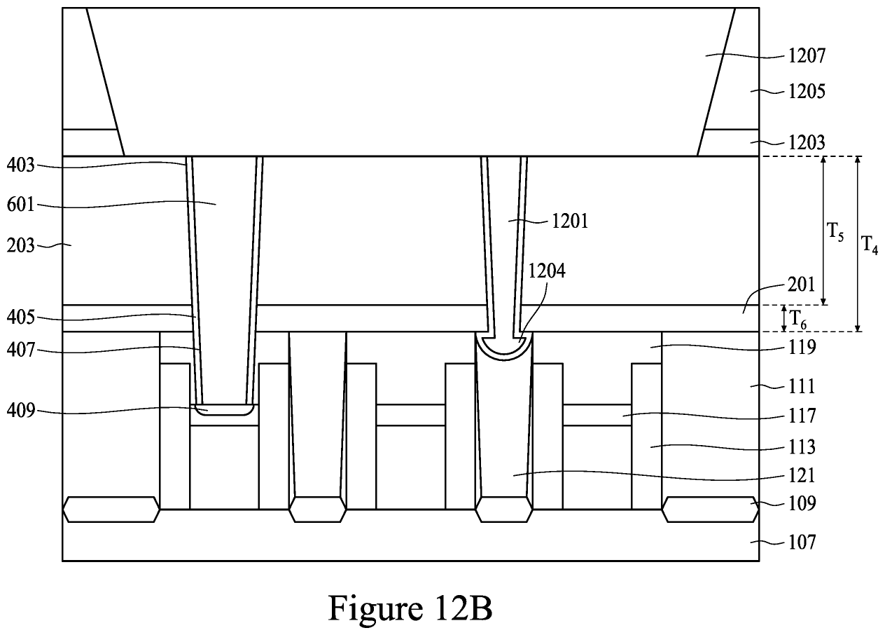

FIG. 12A illustrates that, once the one or more via drain contact materials 1101 has been deposited, the via drain contact material 1101 may be planarized in order to remove any excess material and form the via drain contact 1201. In an embodiment the planarization may be performed using a chemical mechanical polishing process, a grinding process, one or more etching processes, combinations of these, or the like. The via drain contact 1201 (without the recessed portion) may be formed to a fourth thickness T₄ of between about 5 nm and about 40 nm. However, any suitable process may be utilized.

Additionally, once the via drain contact 1201 has been formed using the planarization process, the second ILD layer 203 may have a fifth thickness T₅ of between about 3 nm and about 40 nm. The underlying CESL 201 at this point may have a sixth thickness T₆ of between about 3 nm and about 20 nm. However, any suitable thicknesses may be utilized.

By forming the via drain contact 1201 as described, the via drain contact 1201 may have a bowl shape 1204 embedded within the source/drain contacts 121. In a particular embodiment, the bowl shape may extend into the source/drain contacts 121 between about 2 nm and about 20 nm. However, any suitable dimensions may be utilized.

FIG. 12B illustrates formation of a second CESL 1203, a third ILD layer 1205, and an interconnect 1207. In an embodiment the second CESL 1203 and the third ILD layer 1205 may be sequentially deposited over both the via drain contact 1201 as well as the source/drain via contact 601. In an embodiment the second CESL 1203 may use similar materials and deposition processes as the CESL 201 (described above with respect to FIG. 2) while the third ILD layer 1205 may use similar materials and deposition processes as the second ILD layer 203 (described above with respect to FIG. 2). However, any suitable materials and deposition processes may be utilized.

Once the second CESL 1203 and the third ILD layer 1205 have been formed, an interconnect opening (not separately illustrated in FIG. 12B) is formed through the second CESL 1203 and the third ILD layer 1205 to expose both the via drain contact 1201 and the source/drain via contact 601. In an embodiment the interconnect opening may be formed using one or more photolithographic masking and etching processes. However, any suitable processes may be utilized to for the interconnect opening.

Once the interconnect opening has been formed, one or more conductive materials may be deposited into the interconnect opening. In an embodiment the one or more conductive materials may comprise a barrier layer and fill material (not individually illustrated in FIG. 12B). In an embodiment, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

Once the barrier layer has been formed, the fill material may be deposited in order to fill and/or overfill the remainder of the interconnect opening and electrically connect the via drain contact 1201 and the source/drain via contact 601. In an embodiment the fill material may include copper (Cu), aluminum (Al), tungsten (W) or other suitable conductive material and may be deposited using ALD, CVD, PVD, plating, combinations of these, or the like. However, any suitable material and any suitable process may be utilized.

After the fill material and the barrier layer have been deposited, excess portions of the fill material and the barrier layer that are located outside of the interconnect opening are removed to form the interconnect 1207. In an embodiment the excess portions are removed, for example, using a chemical mechanical polishing process. However, any suitable removal process, such as grinding or even a series of etches, may be utilized to planarize the fill material and the barrier layer.

By utilizing the processes described herein the one or more via drain contact materials 1101 can be deposited using a pseudo-bottom up process without requiring the use of very specific precursors which can otherwise limit which materials can be utilized. For example, by treating the sidewalls of with the dopants (e.g., nitrogen), precursors such as Ru(CO)₁₂, W(CO)6, MoO₂Cl₂ may be utilized to deposit ruthenium, tungsten or molybdenum. Such a process allows for the use of these materials without the use of bottom-up precursors, helping to avoid early pinch-off, holes, or other voids inside of the via drain contact 1201.

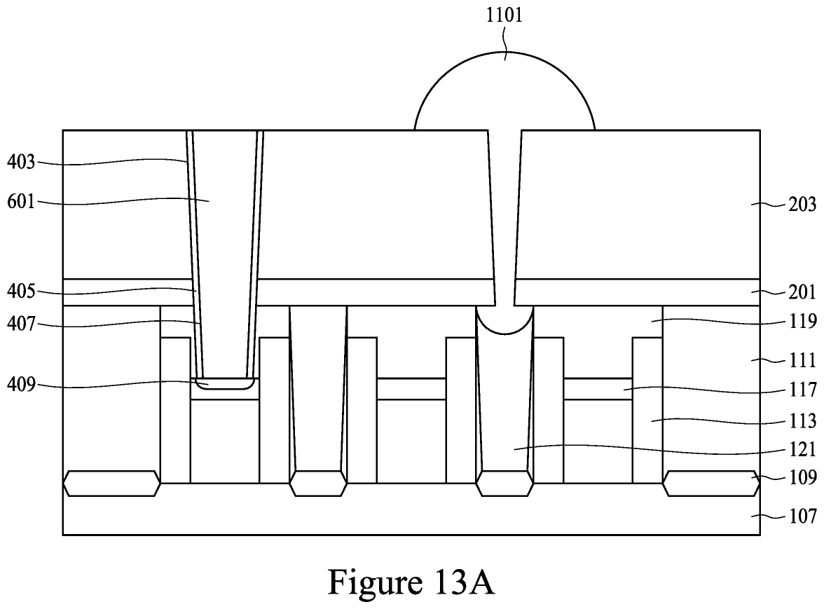

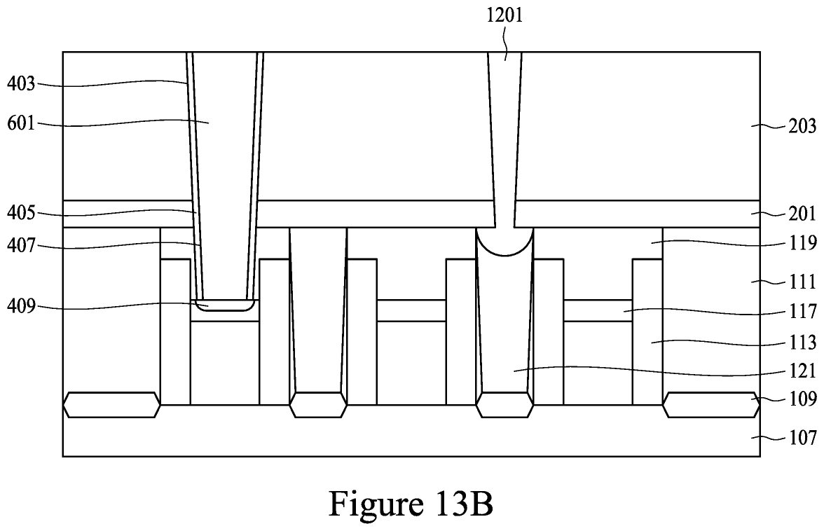

FIGS. 13A-13B illustrate another embodiment in which the second treatment 1001 is not utilized during the formation of the via drain contact 1201. Looking first at FIG. 13A, the via drain contact material 1101 is deposited after formation of the source/drain contact openings 801. The via drain contact material 1101 may be deposited as described above with respect to FIG. 11.

However, in this embodiment, the via drain contact material 1101 is deposited without the intervening second treatment 1001. As such, the fifth treated layer 1003, the sixth treated layer 1005, the seventh treated region, and the eighth treated layer 1009 are not formed and are not present between the via drain contact material 1101 and the second ILD layer 203, between the via drain contact material 1101 and the CESL 201, and between the via drain contact material 1101 and the source/drain contacts 121. As such, the via drain contact material 1101 is formed in direct contact with untreated portions of each of the second ILD layer 203, CESL 201, and source/drain contacts 121.

Turning now to FIG. 13B, the via drain contact material 1101, once deposited, is planarized in order to form the via drain contact 1201. In an embodiment the via drain contact material 1101 may be planarized as described above with respect to FIG. 12A. For example, a chemical mechanical polishing process may be utilized to planarize the via drain contact material 1101. However, any suitable method may be utilized.

However, by not using the second treatment 1001 in this embodiment, the via drain contact 1201 is formed without the intervening second treatment 1001. As such, the fifth treated layer 1003, the sixth treated layer 1005, the seventh treated region, and the eighth treated layer 1009 are not formed and are not present between the via drain contact 1201 and the second ILD layer 203, between the via drain contact 1201 and the CESL 201, and between the via drain contact 1201 and the source/drain contacts 121. As such, the via drain contact 1201 is formed in direct contact with untreated portions of each of the second ILD layer 203, CESL 201, and source/drain contacts 121.

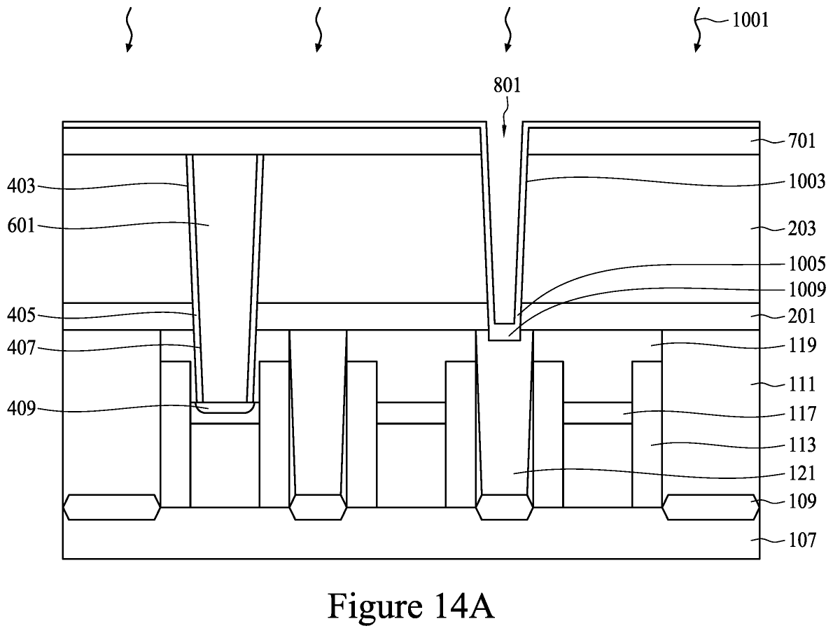

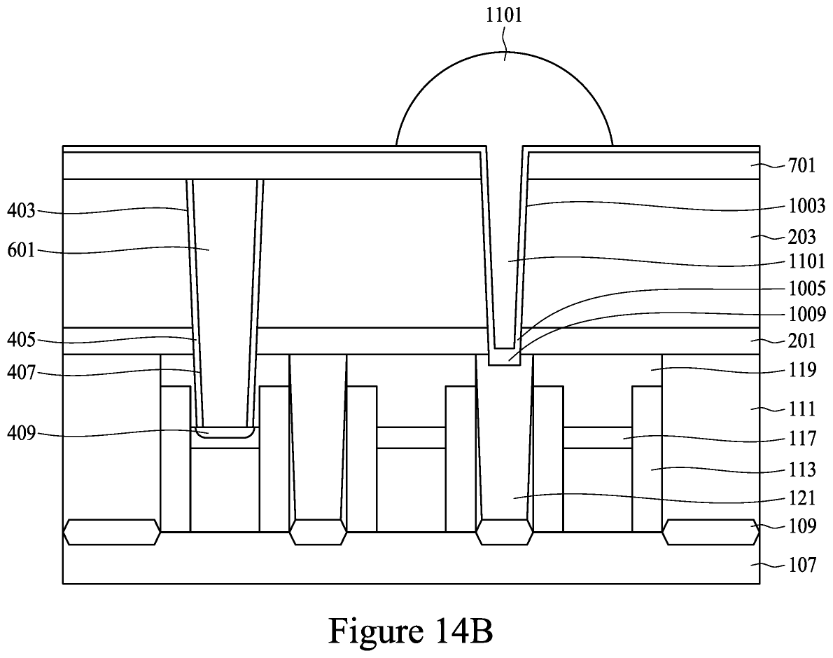

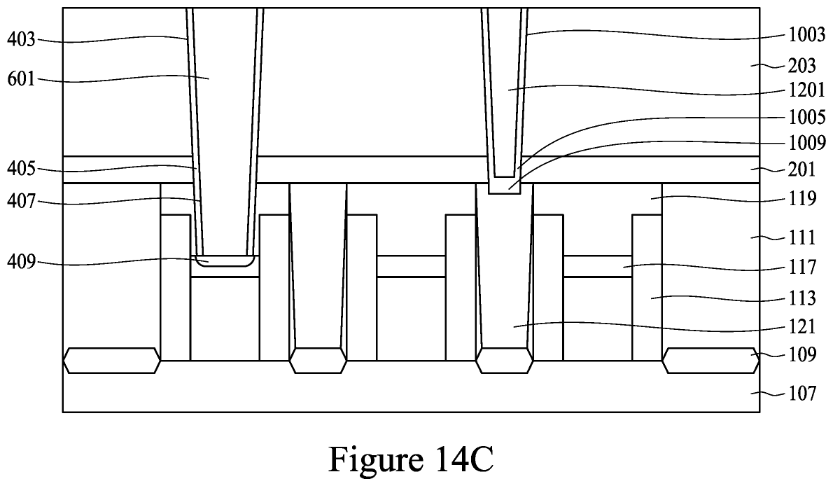

FIGS. 14A-14C illustrate yet another embodiment which utilizes both the first treatment 401 as well as the second treatment 1001. In this embodiment, however, the recessing of the source/drain contacts 121 (as described above with respect to FIG. 9), is not performed. Rather, as illustrated in FIG. 14A, instead of recessing the source/drain contacts 121, the source/drain contacts 121 are utilized as an etch stop during the formation of the source/drain contact openings 801. As such, the top surface of the source/drain contact 121 is planar within the source/drain contact openings 801.

FIG. 14A additionally illustrates that, once the source/drain contact openings 801 have been formed (without the source/drain contacts 121 being recessed), the second treatment 1001 is performed, thereby forming the fifth treated layer 1003 along the sidewalls of the second ILD layer 203, forming the sixth treated layer 1005 along sidewalls of the CESL 201, and forming the eighth treated layer 1009 along the exposed portion of the source/drain contacts 121. However, because there was no recessing of the source/drain contacts 121, the eighth treated region 1009 has a width that is no larger than the width of the source/drain contact openings 801, and the eighth treated layer 1009 does not extend beneath the CESL 201 or the second ILD layer 203.

Turning now to FIG. 14B, once the fifth treated layer 1003, the sixth treated layer 1005, and the eighth treated layer 1009 have been formed using the second treatment 1001, the via drain contact material 1101 is deposited. In an embodiment, the via drain contact material 1101 may be deposited as described above with respect to FIG. 11. However, any suitable materials and processes may be utilized.

However, in this embodiment, the via drain contact material 1101 is deposited without the source/drain contact 121 being recessed. As such, the via drain contact material 1101 is deposited such that it remains outside of the source/drain contact 121, and remains above the first ILD layer 111.

Turning now to FIG. 14C, the via drain contact material 1101, once deposited, is planarized in order to form the via drain contact 1201. In an embodiment the via drain contact material 1101 may be planarized as described above with respect to FIG. 12A. For example, a chemical mechanical polishing process may be utilized to planarize the via drain contact material 1101. However, any suitable method may be utilized.

However, in this embodiment, the via drain contact 1201 is formed without the source/drain contact 121 being recessed. As such, the via drain contact 1201 is remains outside of the source/drain contact 121, has a planar bottom surface, and remains above the first ILD layer 111.

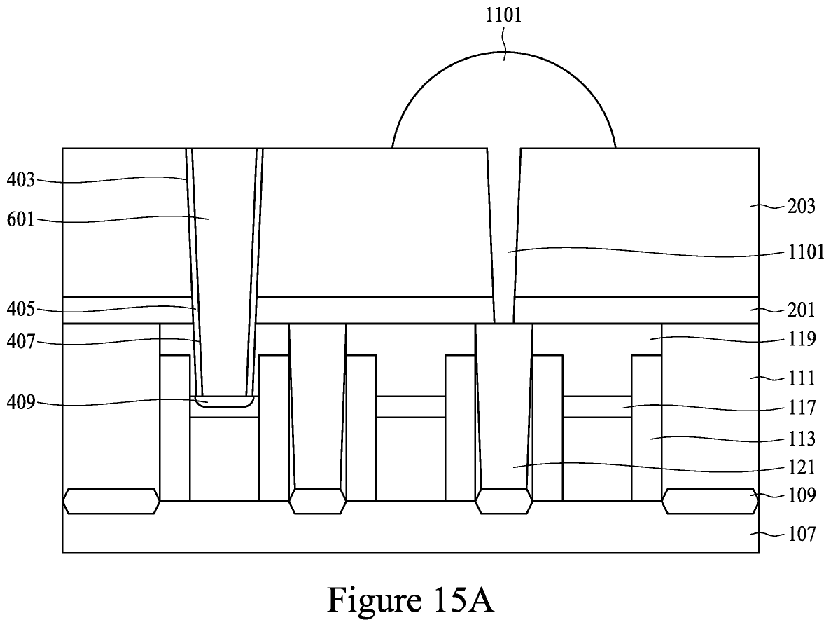

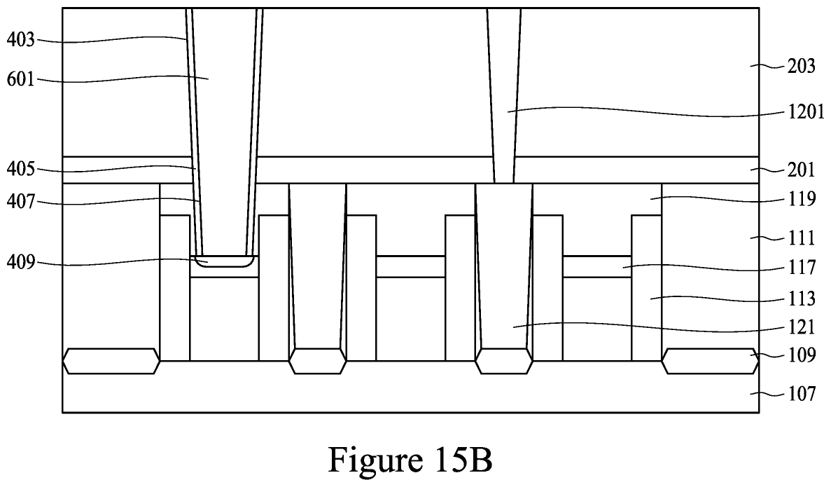

FIGS. 15A-15B illustrate yet another embodiment in which the second treatment 1001 is not utilized during the formation of the via drain contact 1201. In this embodiment, however, the source/drain contact 121 is not recessed (as described above with respect to FIGS. 14A-14C). Looking first at FIG. 15A, the via drain contact material 1101 is deposited after formation of the source/drain contact openings 801, but without the recessing of the source/drain contact 121. The via drain contact material 1101 may be deposited as described above with respect to FIG. 11.

However, in this embodiment, the via drain contact material 1101 is deposited without the intervening second treatment 1001. As such, the fifth treated layer 1003, the sixth treated layer 1005, and the eighth treated layer 1009 are not formed and are not present between the via drain contact material 1101 and the second ILD layer 203, between the via drain contact material 1101 and the CESL 201, and between the via drain contact material 1101 and the source/drain contacts 121. As such, the via drain contact material 1101 is formed in direct contact with untreated portions of each of the second ILD layer 203, CESL 201, and source/drain contacts 121.

Turning now to FIG. 15B, the via drain contact material 1101, once deposited, is planarized in order to form the via drain contact 1201. In an embodiment the via drain contact material 1101 may be planarized as described above with respect to FIG. 12A. For example, a chemical mechanical polishing process may be utilized to planarize the via drain contact material 1101. However, any suitable method may be utilized.

However, by not using the second treatment 1001 in this embodiment, the via drain contact 1201 is formed without the intervening second treatment 1001. As such, the fifth treated layer 1003, the sixth treated layer 1005, and the eighth treated layer 1009 are not formed and are not present between the via drain contact 1201 and the second ILD layer 203, between the via drain contact 1201 and the CESL 201, and between the via drain contact 1201 and the source/drain contacts 121. As such, the via drain contact 1201 is formed in direct contact with untreated portions of each of the second ILD layer 203, CESL 201, and source/drain contacts 121.

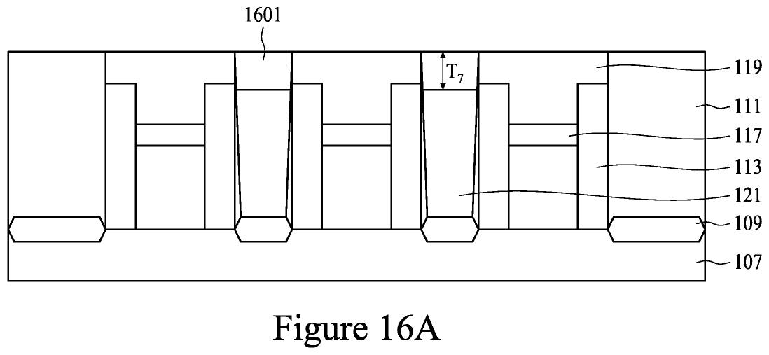

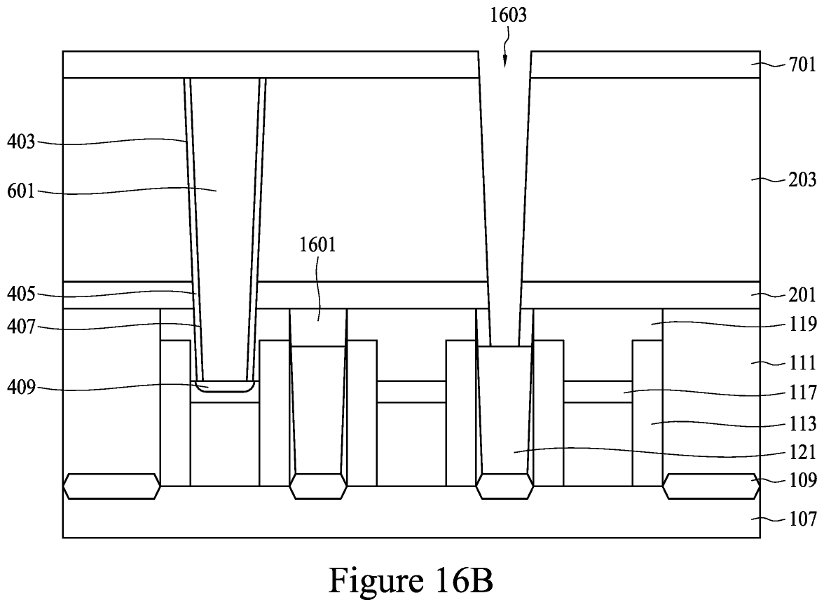

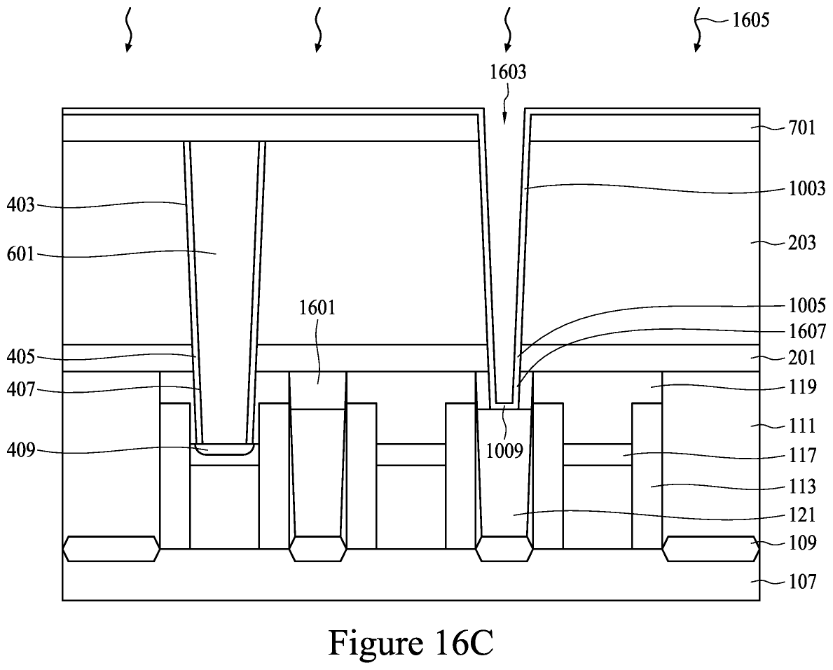

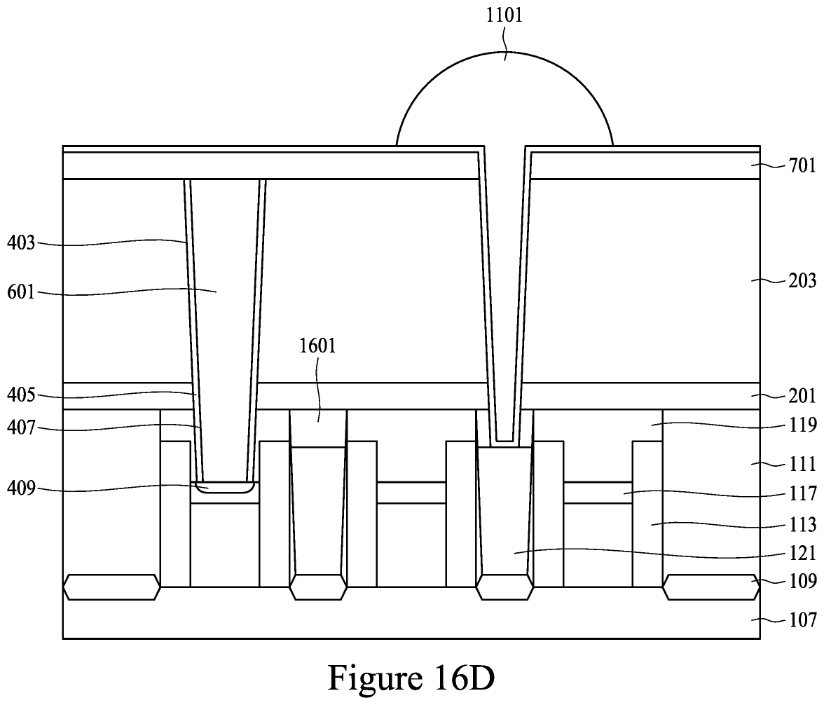

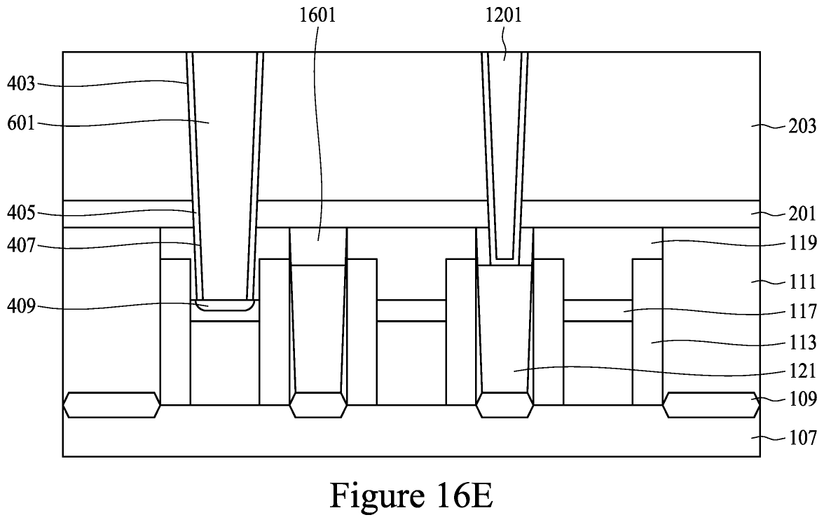

FIGS. 16A-16E illustrate yet another embodiment in which a second hard mask layer 1601 is utilized along with the first hard mask layer 119. In an embodiment the second hard mask layer 1601 may be formed by initially taking the structure as described above with respect to FIG. 1B and recessing the material of the source/drain contacts 121 using, e.g., an etch back process that utilizes etchants selective to the materials of the source/drain contacts 121. The etch back process may be a wet or dry etching process utilizing etchants selective to the materials of the source/drain contacts 121. However, any suitable etching process using any suitable etchants may be utilized.

Once the source/drain contacts 121 have been recessed, the material of the second hard mask layer 1601 may be deposited. In an embodiment the second hard mask layer 1601 may be a dielectric material different from the first hard mask layer 119, and may be, e.g., lanthanum oxide, aluminum oxide, ytterbium oxide, tantalum carbon nitride (TaCN), zirconium silicon (ZrSi), silicon oxycarbonitride (SiOCN), silicon oxycarbide (SiOC), silicon carbonitride (SiCN), zirconium nitride (ZrN), zirconium aluminum oxide (ZrAlO), titanium oxide (TiO), tantalum oxide (TaO), zirconium oxide (ZrO), hafnium oxide (HfO), silicon nitride (SiN), hafnium silicon (HfSi), aluminum oxynitride (AlON), silicon carbide (SiC), zinc oxide, silicon oxide, combinations of these, or the like. The material of the second hard mask layer 1601 may be deposited using a deposition process such as chemical vapor deposition, atomic layer deposition, physical vapor deposition, combinations of these or the like. However, any suitable material and deposition process may be utilized.

Once the material of the second hard mask layer 1601 has been deposited, the material of the second hard mask layer 1601 may be planarized in order to remove excess material from over the first ILD layer 111. In an embodiment the second hard mask layer 1601 may be planarized using a chemical mechanical polishing process, a grinding process, or even a series of etches. Once planarized, the second hard mask layer 1601 may have a seventh thickness T₇ of between about 2 nm and about 20 nm. However, any suitable thickness may be utilized.

Looking now at FIG. 16B, once the second hard mask layer 1601 has been formed, the process continues as described above with respect to FIGS. 2-7. For example, once the second hard mask layer 1601 has been formed, the CESL 201 and the second ILD layer 203 are deposited (as described in FIG. 2), the contact via openings 301 is formed (as described in FIG. 3), the first treatment 401 is performed (as described in FIG. 4), the one or more conductive materials 501 are deposited (as described in FIG. 5) and then planarized (as described in FIG. 6), and the dielectric recap 701 is deposited (as described in FIG. 7).

FIG. 16B further illustrates the formation of a third opening 1603 through the second ILD layer 203, the CESL 201 and the second hard mask layer 1601 to expose the source/drain contact 121. In an embodiment the third opening 1603 may be formed using one or more etching processes. For example, the third opening 1603 may be formed using any combination of acceptable photolithography and suitable etching techniques such as dry etching processes (e.g., plasma etch, reactive ion etch (RIE), physical etching (e.g., ion beam etch (IBE))), wet etching, combinations thereof, and the like. However, any suitable etching processes may be utilized to form the contact via openings.

FIG. 16C illustrates that, once the third opening 1603 has been formed, a third treatment (represented in FIG. 16C by the wavy lines labeled 1605) is performed. In an embodiment the third treatment 1605 may be performed using similar methods as the first treatment 401 and the second treatment 1001, such as by using a plasma process with a precursor such as ammonia. However, any suitable treatment process may be utilized.

In an embodiment in which the third treatment 1605 is an ammonia plasma treatment, the third treatment 1605 may form the fifth treated layer 1003 along the second ILD layer 203, may form the sixth treated layer 1005 along the CESL 201, and the eighth treated layer 1009 along the source/drain contact 121. Additionally, however, in this embodiment the third treatment 1605 may also form a ninth treated layer 1607 along exposed portions of the second hard mask layer 1601.

For example, the third treatment 1605 may cause the dopants (e.g., nitrogen) to diffuse into and react with the material of the second hard mask layer 1601. This diffusion and reaction may cause the formation of the ninth treated layer 1607 along the sidewalls of the second hard mask layer 1601. For example, in an embodiment in which the second hard mask layer 1601 is tantalum carbon nitride, the ninth treated layer 1607 may be tantalum carbon oxynitride. However, any suitable material may be utilized.

Once formed, the ninth treated layer 1607 may have a thickness of between about 2 Å and about 50 Å. Additionally, the ninth treated layer 1607 may have a decreasing concentration of the dopants (e.g., nitrogen) from the exposed surface, with a concentration of the dopant at the exposed surface being between about 0.3%-atomic and about 3%-atomic. However, any suitable concentration may be utilized.

Looking next at FIG. 16D, there is illustrated a continuation of the process, wherein the via drain contact material 1101 is deposited to fill and/or overfill the third opening 1603. In an embodiment the via drain contact material 1101 is deposited as described above with respect to FIG. 11. However, any suitable materials and processes may be utilized.

FIG. 16E illustrates a planarization of the via drain contact material 1101. In an embodiment the planarization may be performed as described above with respect to FIG. 12A to form the via drain contact 1201. However, any suitable method may be utilized.

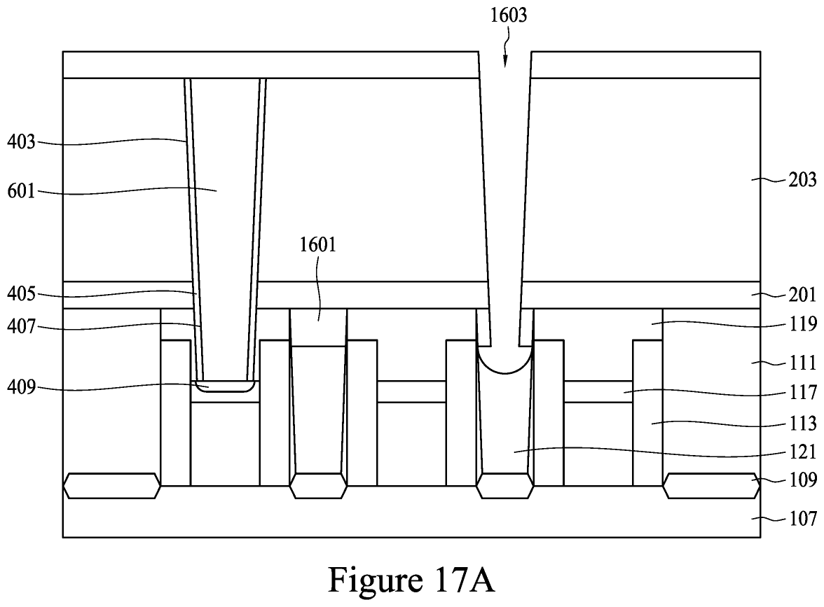

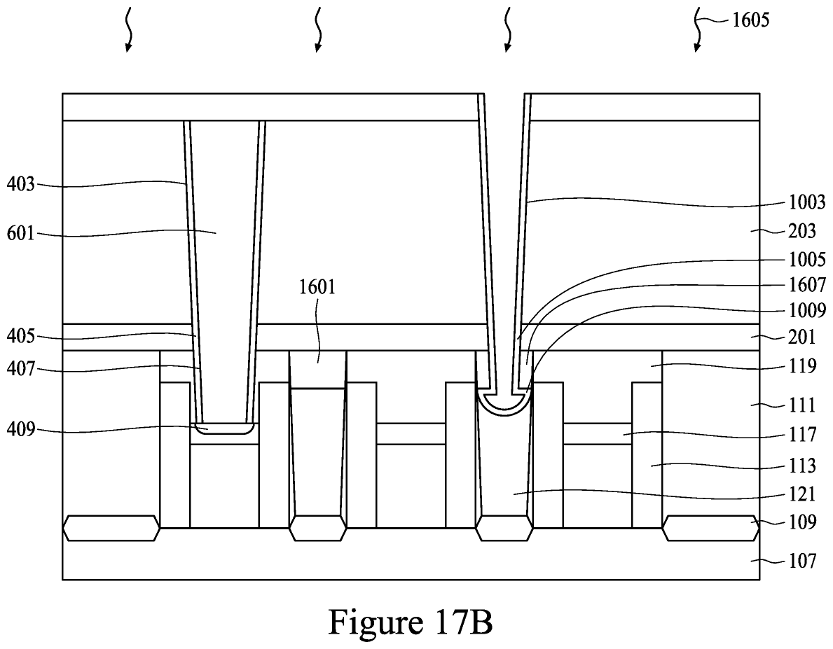

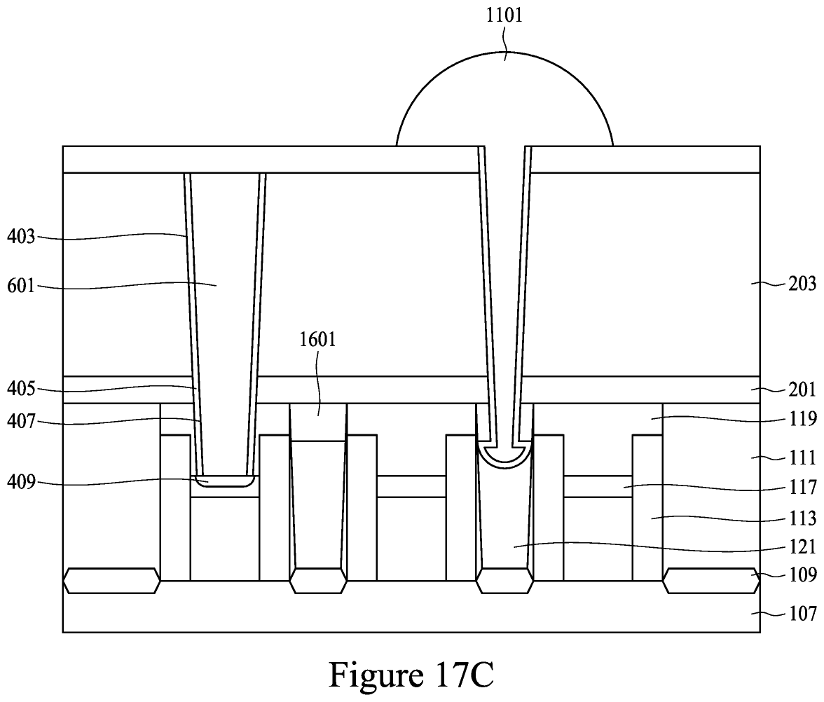

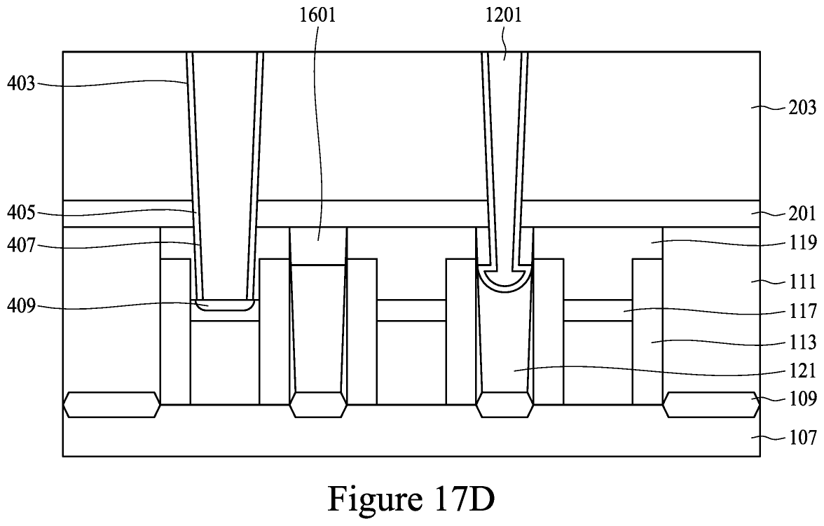

FIGS. 17A-17D illustrate yet another embodiment in which the source/drain contacts 121 are recessed along with the use of the second hard mask layer 1601. In this embodiment, and as illustrated in FIG. 17A, the third opening 1603 is formed as described above with respect to FIG. 16B. However, rather than stopping the formation of the third opening 1603 when the source/drain contacts 121 is exposed, the formation of the third opening 1603 is continued to form the recess within the source/drain contacts 121. In an embodiment the source/drain contacts 121 may be recessed as described above with respect to FIG. 9. However, any suitable method may be utilized.

Looking next at FIG. 17B, once the source/drain contacts 121 have been recessed, the third treatment 1605 may be performed. In an embodiment the third treatment 1605 may be performed as described above with respect to FIG. 16C, such as a plasma treatment using ammonia. In such an embodiment the third treatment 1605 is used to form the fifth treated layer 1003, the sixth treated layer 1005, the ninth treated layer 1607, and the eighth treated layer 1009. In this embodiment, however, the eighth treated layer 1009 is formed along the recess within the source/drain contact 121.

FIG. 17C illustrates that, once the third treatment 1605 has been performed, the third opening 1603, including the recess within the source/drain contacts 121, is filled with the via drain contact material 1101. In an embodiment the via drain contact material 1101 may be deposited to fill and/or overfill the third opening 1603 as described above with respect to FIG. 11. However, any suitable materials and methods of deposition may be utilized.

FIG. 17D illustrates that, once the via drain contact material 1101 have been deposited, the via drain contact material 1101 are planarized in order to form the via drain contact 1201. In an embodiment the via drain contact material 1101 may be planarized as described above with respect to FIG. 12A (e.g., using a chemical mechanical polishing process). However, any suitable method may be utilized.

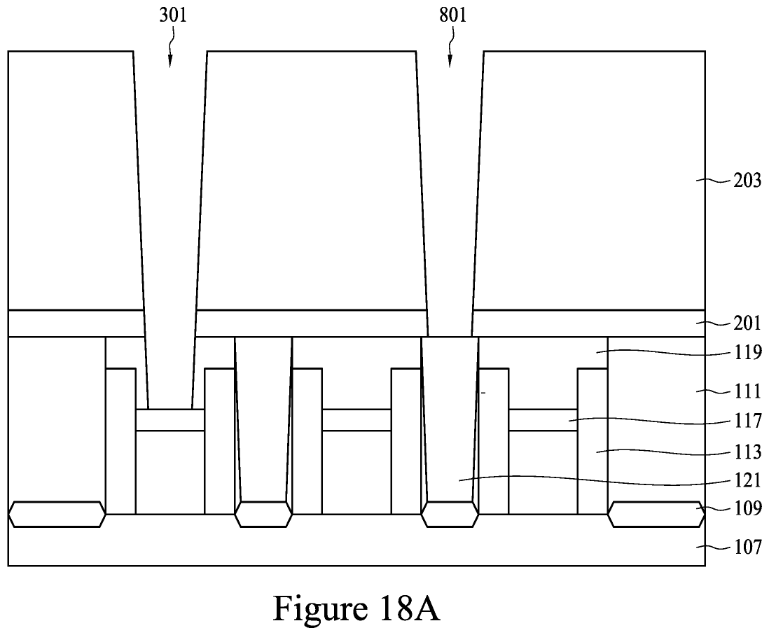

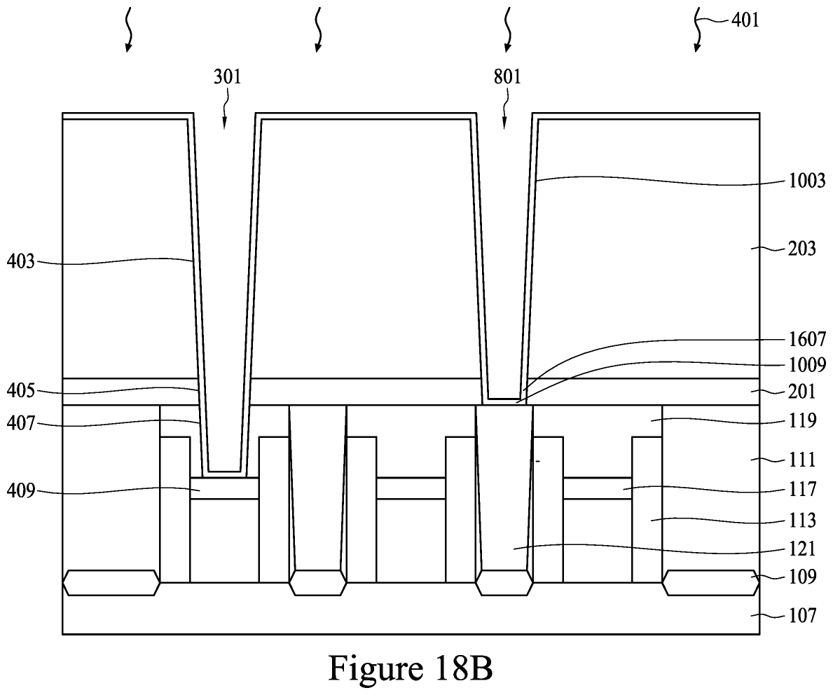

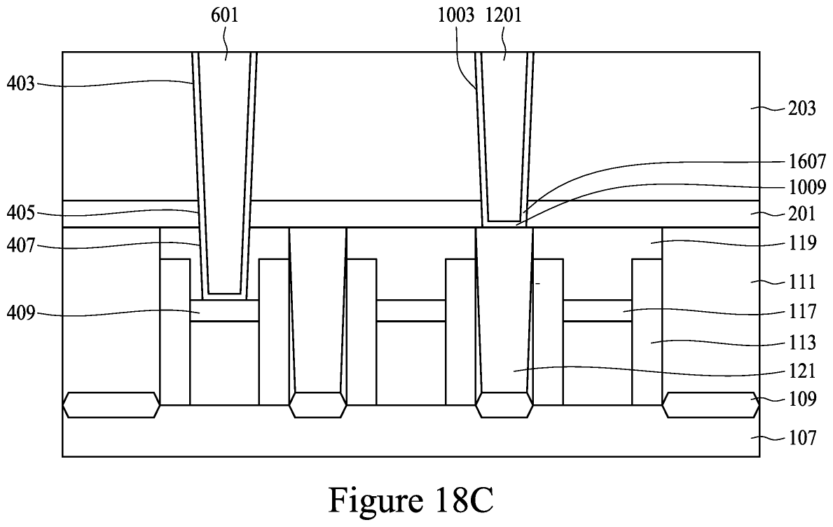

FIGS. 18A-18C illustrate yet another embodiment in which a single treatment process (e.g., the first treatment 401) is utilized in order to treat both the contact via openings 301 and the source/drain contact openings 801. In this embodiment the contact via openings 301 is formed as described above with respect to FIG. 3. However, rather than treating and filling the contact via openings 301 prior to the formation of the source/drain contact openings 801, in this embodiment the source/drain contact openings 801 is formed either simultaneously with the contact via openings 301 or separately, but still prior to the treatment and filling of the contact via openings 301. As such, both the contact via openings 301 and the source/drain contact openings 801 are present prior to the first treatment 401.

FIG. 18B illustrates that, once both the contact via openings 301 and the source/drain contact openings 801 have been formed, the first treatment 401 may be performed on both openings simultaneously. In an embodiment the first treatment 401 may be performed as described above with respect to FIG. 4. For example, a plasma process utilizing ammonia as a precursor may be utilized to treat the exposed surfaces and form the first treated layer 403, the second treated layer 405, the third treated layer 407, the fourth treated layer 409 and to also form the fifth treated layer 1003, the ninth treated layer 1607, and the eighth treated layer 1009. However, any suitable method may be utilized.

FIG. 18C illustrates a filling of the contact via openings 301 and the source/drain contact openings 801. In an embodiment the contact via openings 301 and the source/drain contact openings 801 may be filled by one or more conductive materials (e.g., the one or more conductive materials 501 or the via drain contact material 1101) using materials and processes described above with respect to either FIG. 5 or FIG. 11. However, any suitable materials and methods may be utilized.

FIG. 18C additionally illustrates a planarization process to planarize the one or more conductive materials in order to form the gate via contact 601 and the via drain contact 1201. In an embodiment the one or more conductive materials may be planarized as described above with respect to FIG. 12A (e.g., using a chemical mechanical polishing process). However, any suitable method may be utilized.

By utilizing the processes described herein the gate via contact 601 and/or the via drain contact 1201 can be formed using a pseudo-bottom up process without requiring the use of very specific precursors which can otherwise limit which materials can be utilized. For example, by treating the sidewalls of with the dopants (e.g., nitrogen), precursors such as Ru(CO)₁₂, W(CO)6, MoO₂Cl₂, may be utilized to deposit the desired materials. Such a process allows for the use of these precursors without the use of bottom-up precursors, helping to avoid early pinch-off, holes, or other voids inside of the gate via contact 601 and/or the via drain contact 1201.

In an embodiment, a method of manufacturing a semiconductor device, the method including: depositing an etch stop layer over a first hard mask material, the first hard mask material over a gate stack; depositing an interlayer dielectric over the etch stop layer; forming a first opening through the interlayer dielectric, the etch stop layer, and the first hard mask material, the first opening exposing a conductive portion of the gate stack; and treating sidewalls of the first opening with a first dopant to form a first treated region within the interlayer dielectric, a second treated region within the etch stop layer, a third treated region within the first hard mask material, and a fourth treated region within the conductive portion, wherein after the treating the fourth treated region has a higher concentration of the first dopant than the first treated region. In an embodiment the first dopant comprises nitrogen. In an embodiment the treating the sidewalls comprises at least in part a plasma process. In an embodiment the plasma process utilizes ammonia as a precursor. In an embodiment the fourth treated region has a first concentration of the first dopant of between about 3%-atomic and about 30%-atomic. In an embodiment the method further includes depositing a conductive material within the first opening, the conductive material in physical contact with the first treated region without an intervening liner. In an embodiment the method further includes: forming a second opening through the interlayer dielectric and the etch stop layer to expose a source/drain contact; and depositing a conductive material into the second opening without treating the second opening.

In another embodiment, a method of manufacturing a semiconductor device, the method including: forming a first opening through a dielectric layer, a contact etch stop layer, and a first hard mask material to expose a conductive portion of a gate stack; treating sidewalls of the first opening with a first plasma from a nitrogen-containing precursor; filling the first opening with a first conductive material; forming a second opening through the dielectric layer and the contact etch stop layer to expose a first source/drain contact; treating sidewalls of the second opening with a second plasma; and filling the second opening with a second conductive material. In an embodiment the forming the second opening forms a recess within the first source/drain contact. In an embodiment the forming the second opening does not form a recess within the first source/drain contact. In an embodiment the treating the sidewalls of the first opening and the treating the sidewalls of the second opening are performed simultaneously. In an embodiment the forming the second opening forms the second opening through a second hard mask material overlying the first source/drain contact. In an embodiment the forming the second opening forms a recess within the first source/drain contact. In an embodiment the nitrogen-containing precursor is ammonia.

In yet another embodiment, a semiconductor device includes: a gate stack over a semiconductor fin; a first hard mask material overlying the gate stack, the first hard mask material comprising a first treated region; an etch stop layer overlying the first hard mask material, the etch stop layer comprising a second treated region; a dielectric layer overlying the etch stop layer, the dielectric layer comprising a third treated region; and a conductive material extending through and in physical contact with the first treated region, a second treated region, and a third treated region, wherein the conductive material is also in physical contact with a fourth treated region located within the gate stack. In an embodiment each of the first treated region, the second treated region, the third treated region, and the fourth treated region each comprise nitrogen. In an embodiment the first treated region has a nitrogen concentration of between about 0.3%-atomic and about 3%-atomic. In an embodiment the fourth treated region has a nitrogen concentration of between about 3%-atomic and about 30%-atomic. In an embodiment the semiconductor device further includes a second conductive material extending through and in physical contact with an untreated portion of the dielectric layer and an untreated portion of the etch stop layer to make physical contact with a source/drain contact. In an embodiment the second conductive material extends into the source/drain contact.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of manufacturing a semiconductor device, the method comprising:
depositing an etch stop layer over a first hard mask material, the first hard mask material over a gate stack;
depositing an interlayer dielectric over the etch stop layer;
forming a first opening through the interlayer dielectric, the etch stop layer, and the first hard mask material, the first opening exposing a conductive portion of the gate stack; and
treating sidewalls of the first opening with a first dopant to form a first treated region within the interlayer dielectric, a second treated region within the etch stop layer, a third treated region within the first hard mask material, and a fourth treated region within the conductive portion, wherein after the treating the fourth treated region has a higher concentration of the first dopant than the first treated region.

2. The method of claim 1, wherein the first dopant comprises nitrogen.

3. The method of claim 2, wherein the treating the sidewalls comprises at least in part a plasma process.

4. The method of claim 3, wherein the plasma process utilizes ammonia as a precursor.

5. The method of claim 4, wherein the fourth treated region has a first concentration of the first dopant of between about 3%-atomic and about 30%-atomic.

6. The method of claim 1, further comprising depositing a conductive material within the first opening, the conductive material in physical contact with the first treated region without an intervening liner.

7. The method of claim 1, further comprising:
forming a second opening through the interlayer dielectric and the etch stop layer to expose a source/drain contact; and
depositing a conductive material into the second opening without treating the second opening.

8. A method of manufacturing a semiconductor device, the method comprising:
forming a first opening through a dielectric layer, a contact etch stop layer, and a first hard mask material to expose a conductive portion of a gate stack;
treating sidewalls of the first opening with a first plasma from a nitrogen-containing precursor;
filling the first opening with a first conductive material;
forming a second opening through the dielectric layer and the contact etch stop layer to expose a first source/drain contact;
treating sidewalls of the second opening with a second plasma; and
filling the second opening with a second conductive material.

9. The method of claim 8, wherein the forming the second opening forms a recess within the first source/drain contact.

10. The method of claim 8, wherein the forming the second opening does not form a recess within the first source/drain contact.

11. The method of claim 8, wherein the treating the sidewalls of the first opening and the treating the sidewalls of the second opening are performed simultaneously.

12. The method of claim 8, wherein the forming the second opening forms the second opening through a second hard mask material overlying the first source/drain contact.

13. The method of claim 12, wherein the forming the second opening forms a recess within the first source/drain contact.

14. The method of claim 8, wherein the nitrogen-containing precursor is ammonia.

15. A semiconductor device comprising:
a gate stack over a semiconductor fin;
a first hard mask material overlying the gate stack, the first hard mask material comprising a first treated region;
an etch stop layer overlying the first hard mask material, the etch stop layer comprising a second treated region;
a dielectric layer overlying the etch stop layer, the dielectric layer comprising a third treated region; and
a conductive material extending through and in physical contact with the first treated region, a second treated region, and a third treated region, wherein the conductive material is also in physical contact with a fourth treated region located within the gate stack.

16. The semiconductor device of claim 15, wherein each of the first treated region, the second treated region, the third treated region, and the fourth treated region each comprise nitrogen.

17. The semiconductor device of claim 16, wherein the first treated region has a nitrogen concentration of between about 0.3%-atomic and about 3%-atomic.

18. The semiconductor device of claim 17, wherein the fourth treated region has a nitrogen concentration of between about 3%-atomic and about 30%-atomic.

19. The semiconductor device of claim 15, further comprising a second conductive material extending through and in physical contact with an untreated portion of the dielectric layer and an untreated portion of the etch stop layer to make physical contact with a source/drain contact.

20. The semiconductor device of claim 19, wherein the second conductive material extends into the source/drain contact.
